(19) United States
(12) Patent Application Publication
(10) Pub. No.: US 2024/0004295 A1
(43) Pub. Date: Jan. 4, 2024

(54) RESIST UNDERLAYER FILM-FORMING COMPOSITION CONTAINING A REACTION PRODUCT OF TRIFUNCTIONAL COMPOUND

(71) Applicant: NISSAN CHEMICAL CORPORATION, Tokyo (JP)

(72) Inventors: Shou SHIMIZU, Toyama-shi (JP); Mamoru TAMURA, Toyama-shi (JP)

(73) Assignee: NISSAN CHEMICAL CORPORATION, Tokyo (JP)

(21) Appl. No.: 18/029,314

(22) PCT Filed: Oct. 6, 2021
(86) PCT No.: PCT/JP2021/036900

§ 371 Date: Mar. 29, 2023

(30) Foreign Application Priority Data
Oct. 7, 2020 (JP) 2020-169864

(51) Int. Cl. G03F 7/11; C09D 163/00; C08G 59/32; H01L 21/027

(52) U.S. Cl. CPC G03F 7/11; H01L 21/0274; C08G 59/3245; C09D 163/00

(57) ABSTRACT

A composition forms a resist underlayer film that enables formation of a desired resist pattern; and a method produces a resist pattern and a method produces a semiconductor device, which each use the resist underlayer film-forming composition. This resist underlayer film-forming composition contains a reaction product obtained from: a compound (A) that is dissolved in a solvent and that is represented by formula (1) (in formula (1), A represents an organic group including an aliphatic ring, an aromatic ring, or a heterocyclic ring); a compound (B) having two functional groups that are reactive with respect to an epoxy group; and a compound (C) having one functional group that is reactive with respect to an epoxy group.

### TECHNICAL FIELD

The present invention relates to a composition used in a lithography process for the semiconductor production, particularly in a cutting-edge lithography (e.g., ArF, EUV, or EB lithography) process. In addition, the present invention relates to a method for producing a substrate having a resist pattern using the resist underlayer film and a method for producing a semiconductor device.

### BACKGROUND ART

In the production of semiconductor devices, microfabrication by lithography using a resist composition has conventionally been conducted. The microfabrication is a fabrication method in which a thin film of a photoresist composition is formed on a semiconductor substrate, such as a silicon wafer, and irradiated with an active ray of light, such as an ultraviolet light, through a mask pattern having a pattern for a device, and subjected to development, and the substrate is subjected to etching treatment using the obtained photoresist pattern as a protective film, forming very small unevenness corresponding to the pattern in the surface of the substrate. In recent years, semiconductor devices are further increased in the integration degree, and, with respect to the active ray of light used for microfabrication, an i-line (wavelength: 365 nm), a KrF excimer laser (wavelength: 248 nm), and an ArF excimer laser (wavelength: 193 nm) have been conventionally used, and further the practical use of an EUV light (wavelength: 13.5 nm) or an EB (electron beam) in the most advanced microfabrication is studied. The use of such a ray of light having a short wavelength has a serious problem in that formation of a resist pattern is failed due to influences by a semiconductor substrate and others. As a method for solving the problem, a method of forming a resist underlayer film between a resist and a semiconductor substrate has been widely studied.

Patent Literature 1 discloses a resist underlayer film-forming composition having a disulfide structure. Patent Literature 2 discloses an antireflection film forming composition for lithography.

### CITATION LIST

### Patent Literature

Patent Literature 1: WO 2019/151471
Patent Literature 2: WO 02/086624

### SUMMARY OF INVENTION

### Technical Problem

The properties required for the resist underlayer film include, for example, properties that intermixing of the resist underlayer film with a resist film formed thereon does not occur (the resist underlayer film is insoluble in a resist solvent), and that the resist underlayer film has a higher dry etching rate, as compared to the resist film.

In the lithography using EUV exposure, the formed resist pattern has a line width as small as 32 nm or less, and the resist underlayer film formed and used for EUV exposure has a smaller thickness than any conventional film. In the formation of such a thin film, for example, pinhole or aggregation is likely to be caused due to influence of the surface of a substrate and the polymer used and others, and thus it has been difficult to form a uniform film having no defect.

On the other hand, when forming a resist pattern, in the development step, a method is employed in which, using a solvent capable of dissolving the resist film, generally using an organic solvent, the unexposed portion of the resist film is removed so that the exposed portion of the resist film remains as a resist pattern (negative development process), or a method is employed in which the exposed portion of the resist film is removed so that the unexposed portion of the resist film remains as a resist pattern (positive development process). In such negative and positive development processes, an improvement of the adhesion of the resist pattern is an important task.

Further, suppression of unfavorable LWR (line width roughness) when forming a resist pattern, formation of a resist pattern having an excellent rectangular form, and improvement of the resist sensitivity are desired.

An object of the present invention is to provide a composition which has solved the above-mentioned problems, and which is for use in forming a resist underlayer film that is capable of forming a desired resist pattern, and a method for forming a resist pattern using the resist underlayer film-forming composition.

### Solution to Problem

The present invention encompasses the followings.

[1]

A resist underlayer film-forming composition comprising a solvent and a reaction product of:

Compound (A) represented by the following formula (1):

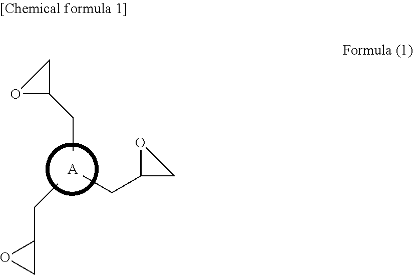

wherein A represents an organic group having an aliphatic ring, aromatic ring, or heterocycle,
Compound (B) having two functional groups having reactivity with an epoxy group, and
Compound (C) having a functional group having reactivity with an epoxy group,
wherein the reaction product is dissolved in the solvent.

[2]

The resist underlayer film-forming composition according to [1], wherein A in formula (1) is a heterocycle.

[3]

The resist underlayer film-forming composition according to [2], wherein the heterocycle is a triazine.

[4]

The resist underlayer film-forming composition according to any one of [1] to [3], wherein Compound (B) is a compound having two functional groups having reactivity with an epoxy group, and having an aliphatic ring, aromatic ring, heterocycle, fluorine atom, iodine atom, or sulfur atom.

[5]

The resist underlayer film-forming composition according to any one of [1] to [4], wherein Compound (C) is a compound having a functional group having reactivity with an epoxy group, and having an aliphatic or aromatic ring optionally substituted with a substituent.

[6]

A resist underlayer film-forming composition comprising a solvent and a reaction product (a) of:
Compound (A) represented by the following formula (1):

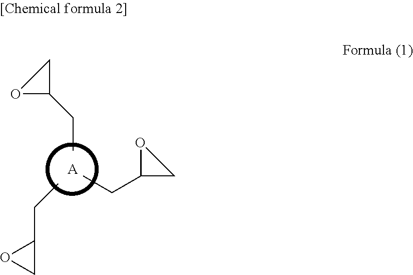

wherein A represents an organic group having an aliphatic ring, aromatic ring, or heterocycle, and
Compound (B) having two functional groups having reactivity with an epoxy group, and having no disulfide bond,
wherein the reaction product (a) is dissolved in the solvent.

[7]

The resist underlayer film-forming composition according to any one of [1] to [6], further comprising an acid generator.

[8]

The resist underlayer film-forming composition according to any one of [1] to [7], further comprising a crosslinking agent.

[9]

A resist underlayer film which is a baked material of an applied film comprising the resist underlayer film-forming composition according to any one of [1] to [8].

[10]

A method for producing a patterned substrate, comprising the steps of:
applying the resist underlayer film-forming composition according to any one of claims 1 to 8 onto a semiconductor substrate and baking the applied composition to form a resist underlayer film;
applying a resist onto the resist underlayer film and baking the applied resist to form a resist film;
subjecting the semiconductor substrate covered with the resist underlayer film and the resist to exposure; and
subjecting the exposed resist film to development and patterning.

[11]

A method for producing a semiconductor device, comprising the steps of:
forming a resist underlayer film comprising the resist underlayer film-forming composition according to any one of [1] to [8] on a semiconductor substrate;
forming a resist film on the resist underlayer film;
irradiating the resist film with a light or electron beam and then developing the irradiated resist film to form a resist pattern;
etching the resist underlayer film through the formed resist pattern to form a patterned resist underlayer film; and
processing the semiconductor substrate using the patterned resist underlayer film.

[12]

A method for producing a reaction product, especially a reaction product for a resist underlayer film-forming composition, the method comprising the step of carrying out in a solvent a reaction of a mixture containing:
Compound (A) represented by the following formula (1):

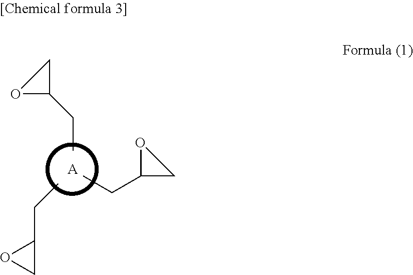

wherein A represents an organic group having an aliphatic ring, aromatic ring, or heterocycle,
Compound (B) having two functional groups having reactivity with an epoxy group, and
Compound (C) having a functional group having reactivity with an epoxy group.

[13]

A method for producing a resist underlayer film-forming composition, comprising the step of further mixing the reaction product according to [12] with a solvent which is the same as or different from the solvent used for the reaction.

[14]

A method for producing a reaction product, especially a reaction product for a resist underlayer film-forming composition, the method comprising the step of carrying out in a solvent a reaction of a mixture containing:
Compound (A) represented by the following formula (1):

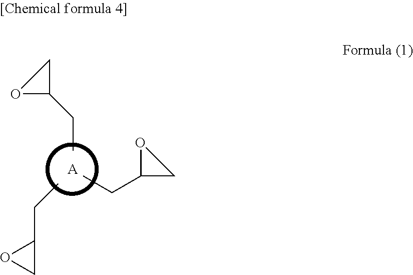

wherein A represent an organic group having an aliphatic ring, aromatic ring, or heterocycle, and

Compound (B) having two functional groups having reactivity with an epoxy group, and having no disulfide bond.

[15]

A method for producing a resist underlayer film-forming composition, comprising the step of further mixing the reaction product according to [14] with a solvent which is the same as or different from the solvent used for the reaction.

### Advantageous Effects of Invention

The resist underlayer film-forming composition of the present invention has excellent application properties to a semiconductor substrate to be processed and can achieve an improvement of the adhesion of an interface between the resist and the resist underlayer film when forming a resist pattern and an improvement of the sensitivity.

The resist underlayer film-forming composition of the present invention exhibits remarkable advantageous effects especially when used in EUV light (wavelength: 13.5 nm) or EB (electron beam) exposure.

### DESCRIPTION OF EMBODIMENTS

### Resist Underlayer Film-Forming Composition

The resist underlayer film-forming composition of the present invention comprises a solvent and a reaction product from a reaction of a mixture containing:

Compound (A) represented by the following formula (1):

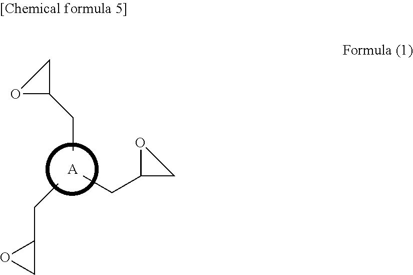

wherein A represents an organic group having an aliphatic ring, aromatic ring, or heterocycle,
Compound (B) having two functional groups having reactivity with an epoxy group, and
Compound (C) having a functional group having reactivity with an epoxy group,
wherein the reaction product is soluble in the solvent.

With respect to the mixture of compounds (A) to (C), the molar ratio (C)/((A)+(B)) is preferably within the range of 0.5 to 2. When the molar ratio (C)/((A)+(B)) is in the range of from 0.5 to 2 in the reaction of the mixture of compounds (A) to (C), an excessive increase of the weight average molecular weight of the reaction product is suppressed, enabling production of the reaction product in which a certain amount of Compound (C) is present at each end of the molecule of the reaction product. When Compound (C) is present at the end, the reaction product is improved in solubility in the solvent.

The reaction product of Compound (A), Compound (B), and Compound (C) may be obtained by, for example, conducting a reaction according to the method described in the Examples below.

The molar ratio of Compound (A), Compound (B), and Compound (C) mixed in the reaction, i.e., (C)/((A)+(B)) is within the range of 0.5 to 2, but may be within the range of 0.5 to 1.9, may be within the range of 0.5 to 1.8, may be within the range of 0.5 to 1.7, may be within the range of 0.5 to 1.6, may be within the range of 0.5 to 1.5, may be within the range of 0.5 to 1.4, may be within the range of 0.5 to 1.3, may be within the range of 0.5 to 1.2, may be within the range of 0.5 to 1.1, or may be within the range of 0.5 to 1.0.

The expression “soluble in the solvent” means that the state in which the reaction product is uniformly dissolved in the below-mentioned solvent is maintained. For example, it means that even after the composition has been stored under predetermined conditions (for example, at a temperature within the range of from 5 to 40° C. for one month), no deposit of the reaction product (including a gel) is visually observed, and filtration of all of 100 mL of the composition using a microfilter having a pore diameter of 0.05 to 0.1 μm is possible within 30 minutes.

Examples of the functional groups having reactivity with an epoxy group include a hydroxy group, an acyl group, an acetyl group, a formyl group, a benzoyl group, a carboxy group, a carbonyl group, an amino group, an imino group, a cyano group, an azo group, an azi group, a thiol group, a sulfo group, an allyl group, and an acid anhydride, but a carboxy group is preferred.

The reaction product has a partial structure represented by the following formula (1-1):

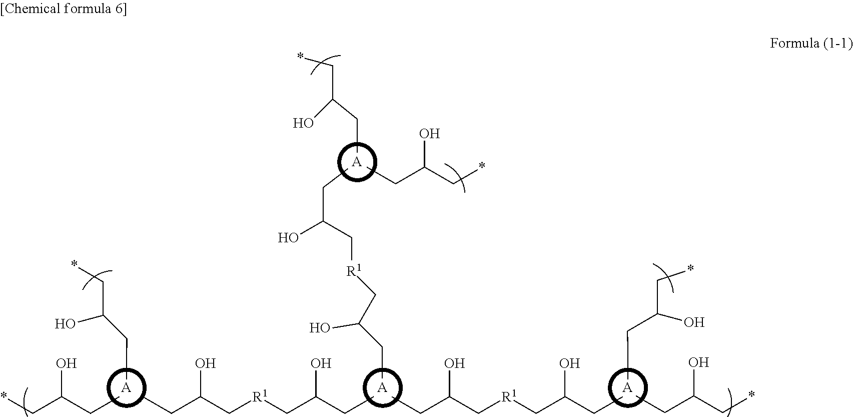

wherein A represents an organic group having an aliphatic ring, aromatic ring, or heterocycle; R¹ represents a residue derived from Compound (B); and * represents a bonding site with Compound (B) or Compound (C).

The lower limit of the weight average molecular weight of the reaction product is, for example, 500, 1,000, 2,000, or 3,000, and the upper limit of the weight average molecular weight of the reaction product is, for example, 30,000, 20,000, or 10,000.

R¹ is preferably the below-mentioned divalent organic group having an aliphatic ring, aromatic ring, heterocycle, or sulfur atom.

The resist underlayer film-forming composition of the present invention may contain a solvent and a reaction product (a) from a reaction of a mixture containing:

Compound (A) represented by the following formula (1):

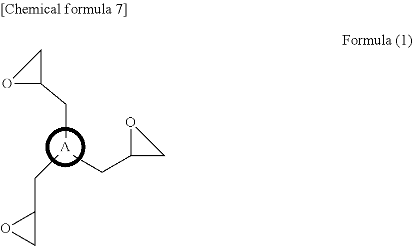

wherein A represents an organic group having an aliphatic ring, aromatic ring, or heterocycle, and

Compound (B) having two functional groups having reactivity with an epoxy group, and having no disulfide bond.

In the case of reaction product (a), the molar ratio of Compound (A) and Compound (B) having two functional groups having reactivity with an epoxy group, and having no disulfide bond is, for example, within the range of 1:0.1 to 10, preferably 1:1 to 5, further preferably 1:3.

The lower limit of the weight average molecular weight of reaction product (a) is, for example, 500, 1,000, 2,000, or 3,000, and the upper limit of the weight average molecular weight of the reaction product is, for example, 30,000, 20,000, or 10,000.

### Compound (A)

With respect to the compound represented by formula (1) (Compound (A)), there is no particular limitation as long as the compound has an organic group having an aliphatic ring, aromatic ring, or heterocycle and exhibits the advantageous effects of the present invention, but examples of the compounds are shown blow.

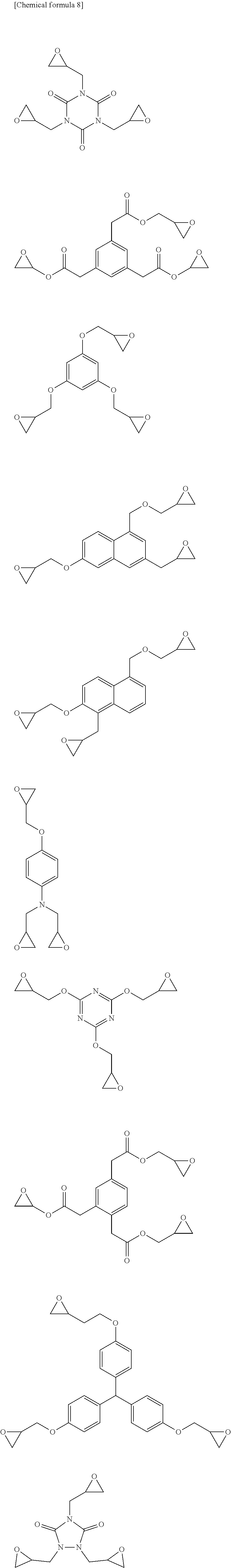

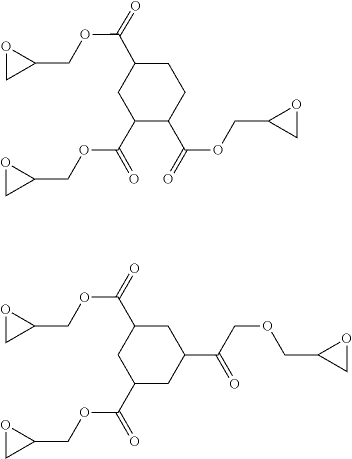 [SMILES: O=C(OCC1CO1)C1CCC(C(=O)OCC2CO2)C(C(=O)OCC2CO2)C1 ; O=C(COCC1CO1)C1CC(C(=O)OCC2CO2)CC(C(=O)OCC2CO2)C1]

A in formula (1) above is preferably a heterocycle. The heterocycle is preferably a triazine. The heterocycle is preferably 1,2,3-triazine. The heterocycle is preferably triazinetrione.

### Compound (B)

With respect to Compound (B), there is no particular limitation as long as the compound exhibits the advantageous effects of the present invention, but preferred is a compound having two functional groups having reactivity with an epoxy group, and having an aliphatic ring, aromatic ring, heterocycle, fluorine atom, iodine atom, or sulfur atom. It is preferred that the sulfur atom is contained in the compound in the form of a sulfide bond, disulfide bond, or sulfonyl group.

Examples of Compound (B) are shown blow.

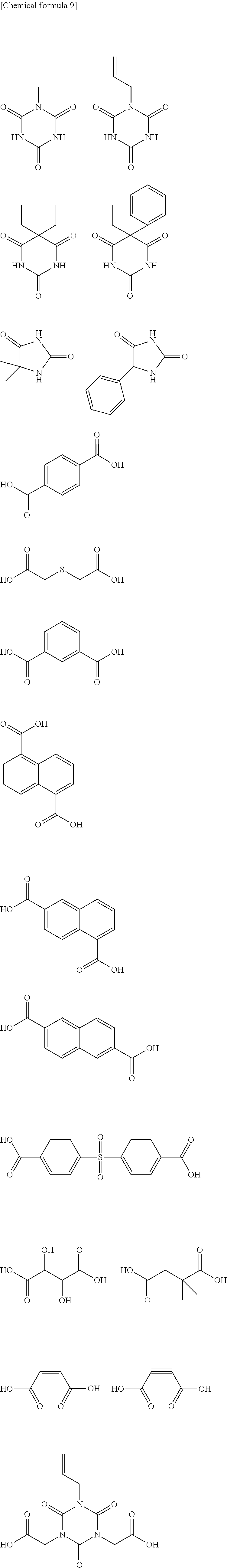

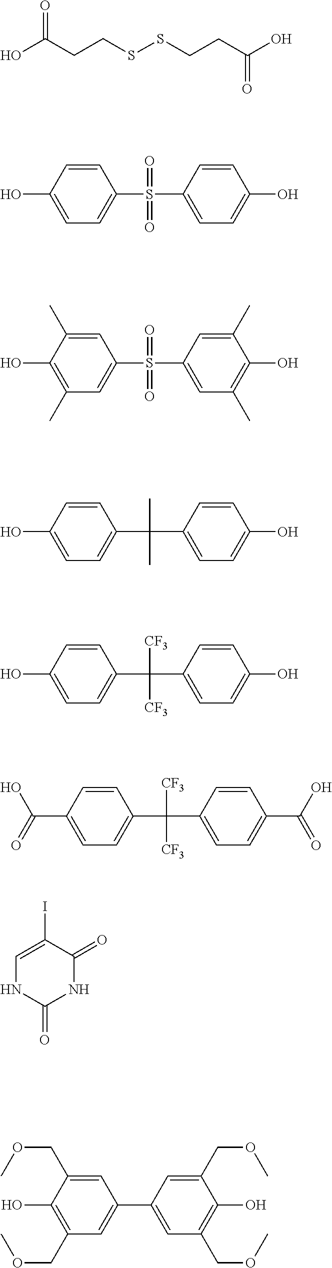

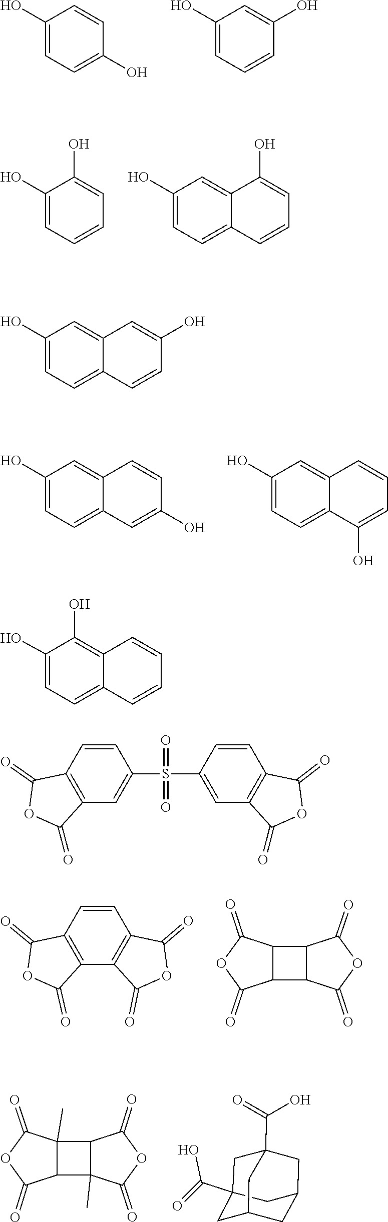

When Compound (B) is an acid dianhydride, the carboxy group which is unreacted with the epoxy group may be free, and may have been reacted with at least one compound represented by the following formula (3d):

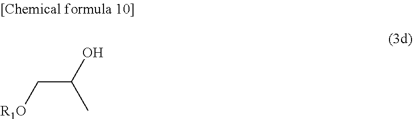

wherein R₁ represents a methyl group or an ethyl group.

### Compound (C)

With respect to Compound (C), there is no particular limitation as long as the compound exhibits the advantageous effects of the present invention, but preferred is a compound having a functional group having reactivity with an epoxy group, and having an aliphatic or aromatic ring optionally substituted with a substituent.

Compound (C) may have an aliphatic ring optionally substituted with a substituent.

The aliphatic ring is preferably a monocyclic or polycyclic aliphatic ring having 3 to 10 carbon atoms. Examples of the monocyclic or polycyclic aliphatic rings having 3 to 10 carbon atoms include cyclopropane, cyclobutane, cyclopentane, cyclohexane, cyclohexene, cycloheptane, cyclooctane, cyclononane, cyclodecane, spirobicyclopentane, bicyclo[2.1.0]pentane, bicyclo[3.2.1]octane, tricyclo[3.2.1.0^{2,7}]octane, spiro[3,4]octane, norbornane, norbornene, and tricyclo[3.3.1.1^{3,7}]decane (adamantane).

The polycyclic aliphatic ring is preferably a bicyclo-ring or a tricyclo-ring.

Examples of the bicyclo-rings include norbornane, norbornene, spirobicyclopentane, bicyclo[2.1.0]pentane, bicyclo[3.2.1]octane, and spiro[3,4]octane.

Examples of the tricyclo-rings include tricyclo[3.2.1.0^{2,7}]octane and tricyclo[3.3.1.1^{3,7}]decane (adamantane).

The expression “aliphatic ring optionally substituted with a substituent” means that at least one hydrogen atom of the aliphatic ring is optionally replaced by the below-mentioned substituent.

The substituent is preferably selected from a hydroxy group, a linear or branched alkyl group having 1 to 10 carbon atoms, an alkoxy group having 1 to 20 carbon atoms, an aryl group having 6 to 40 carbon atoms, an acyloxy group having 1 to 10 carbon atoms and optionally being interrupted by an oxygen atom, and a carboxy group.

Examples of the alkoxy groups having 1 to 20 carbon atoms include a methoxy group, an ethoxy group, a n-propoxy group, an i-propoxy group, a n-butoxy group, an i-butoxy group, a s-butoxy group, a t-butoxy group, a n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, a n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl−1-methyl-n-propoxy group, a 1-ethyl-2-methyl-n-propoxy group, a cyclopentyloxy group, a cyclohexyloxy group, a norbornyloxy group, an adamantyloxy group, an adamantanemethyloxy group, an adamantaneethyloxy group, a tetracyclodecanyloxy group, and a tricyclodecanyloxy group.

Examples of the aryl groups having 6 to 40 carbon atoms include a benzyl group, a naphthyl group, an anthracenyl group, a phenanthrenyl group, and a pyrenyl group, and, of these, preferred is a phenyl group.

The acyloxy group having 1 to 10 carbon atoms means a group represented by the following formula (4):

[Chemical Formula 11]

Z—COO—* Formula (4)

wherein Z is a hydrogen atom, or an alkyl group having 1 to 9 carbon atoms among the above-mentioned alkyl group having 1 to 10 carbon atoms, wherein the alkyl group is optionally substituted with the above-mentioned substituent and optionally interrupted by an oxygen atom or an ester linkage and optionally has an allyl group or a propargyl group; and * represents a bonding site with the above-mentioned “aliphatic ring”.

The aliphatic ring preferably has at least one unsaturated bond (for example, a double bond or a triple bond). The aliphatic ring preferably has one to three unsaturated bonds. The aliphatic ring preferably has one or two unsaturated bonds. The unsaturated bond is preferably a double bond.

Specific examples of the compounds having the aliphatic ring optionally substituted with a substituent include the below-shown compounds. Further specific examples include compounds corresponding to the compounds of the above specific examples, in which the carboxy group is replaced by a hydroxy group, an acyl group, an acetyl group, a formyl group, a benzoyl group, a carboxy group, a carbonyl group, an amino group, an imino group, a cyano group, an azo group, an azi group, a thiol group, a sulfo group, or an allyl group.

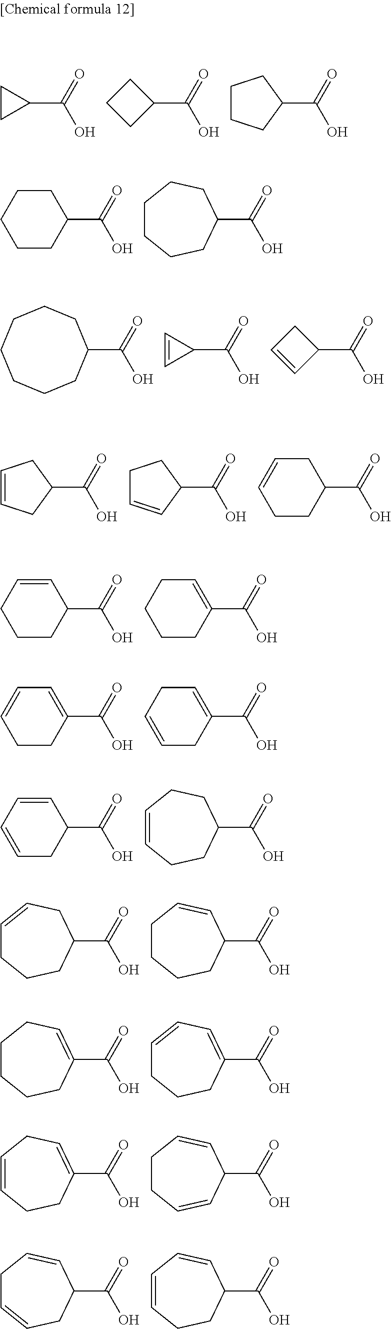

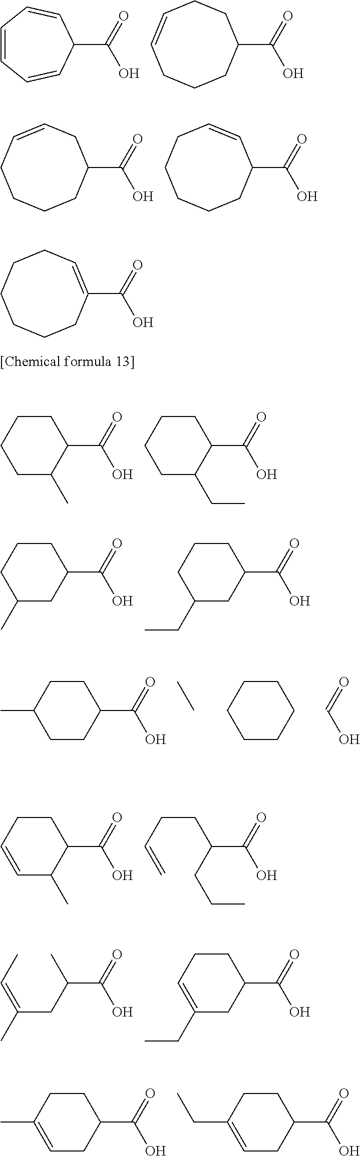

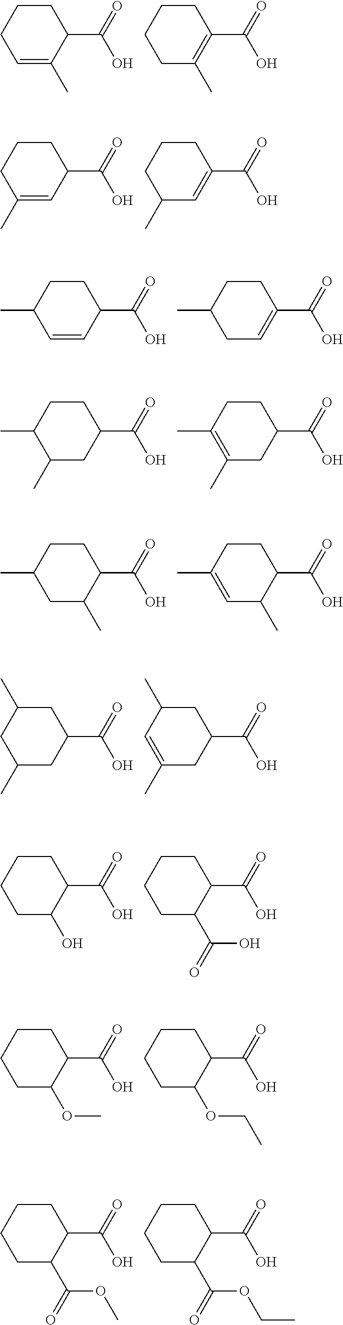

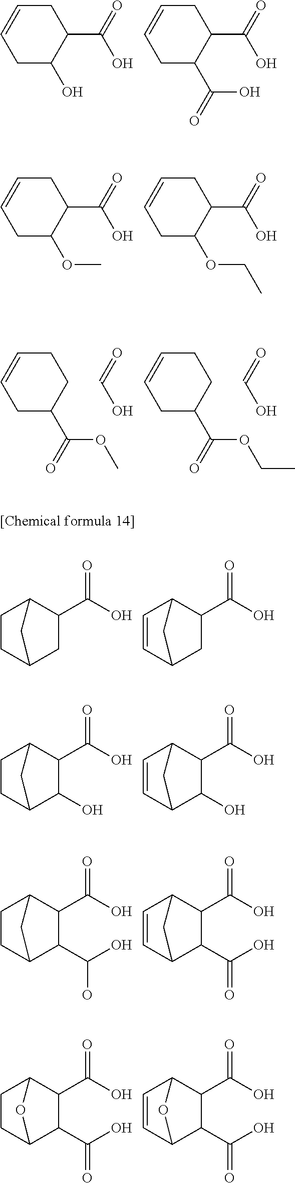

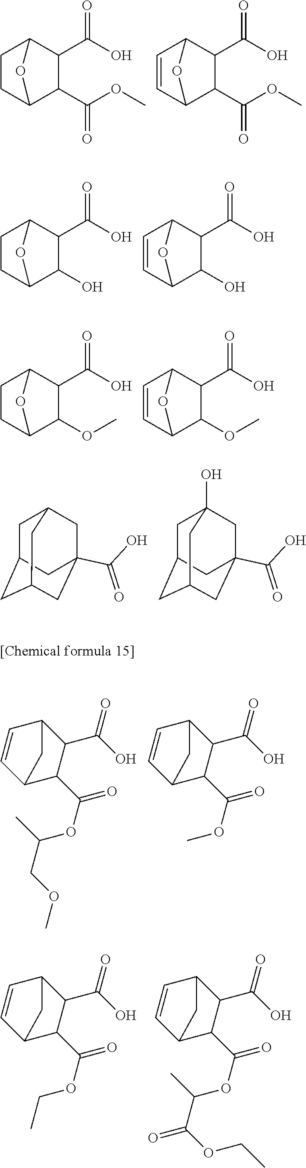

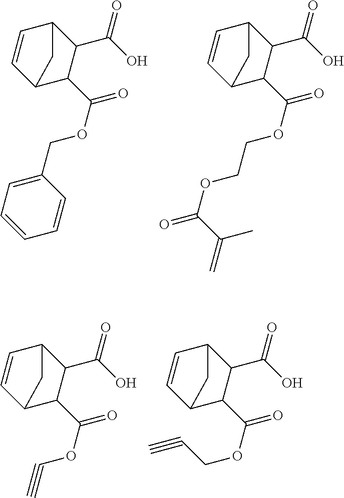

Compound (C) is preferably represented by the following formulae (11) and (12):

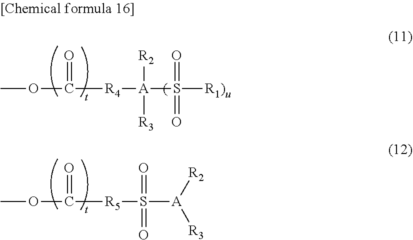

wherein, in formulae (11) and (12), R₁ represents an alkyl group having 1 to 6 carbon atoms and optionally having a substituent, a phenyl group, a pyridyl group, a halogeno group, or a hydroxy group; R₂ represents a hydrogen atom, an alkyl group having 1 to 6 carbon atoms, a hydroxy group, a halogeno group, or an ester group represented by —C(═O)O—X wherein X represents an alkyl group having 1 to 6 carbon atoms and optionally having a substituent; R₃ represents a hydrogen atom, an alkyl group having 1 to 6 carbon atoms, a hydroxy group, or a halogeno group; R₄ represents a direct bond or a divalent organic group having 1 to 8 carbon atoms; R₅ represents a divalent organic group having 1 to 8 carbon atoms; A represents an aromatic ring or an aromatic heterocycle; t represents 0 or 1; and u represents 1 or 2.

With respect to formulae (11) and (12), the entire disclosure of WO 2015/163195 is incorporated into the present application by reference.

The polymer terminal structure represented by formulae (11) and (12) may be produced by a reaction of the above-mentioned polymer and a compound represented by the following formula (1a) and/or a compound represented by the following formula (2a):

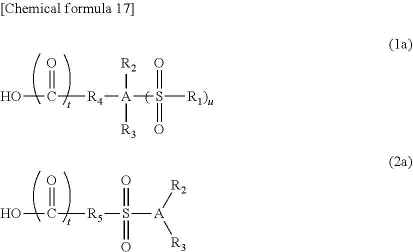

wherein the meaning of the characters and numerals in formulae (1a) and (2a) is as described above for formulae (11) and (12).

Examples of the compound represented by formula (1a) include compounds represented by the following formulae. Further specific examples include compounds corresponding to the above-mentioned compounds, in which the carboxy group or hydroxy group is replaced by an acyl group, an acetyl group, a formyl group, a benzoyl group, a carboxy group, a carbonyl group, an amino group, an imino group, a cyano group, an azo group, an azi group, a thiol group, a sulfo group, or an allyl group.

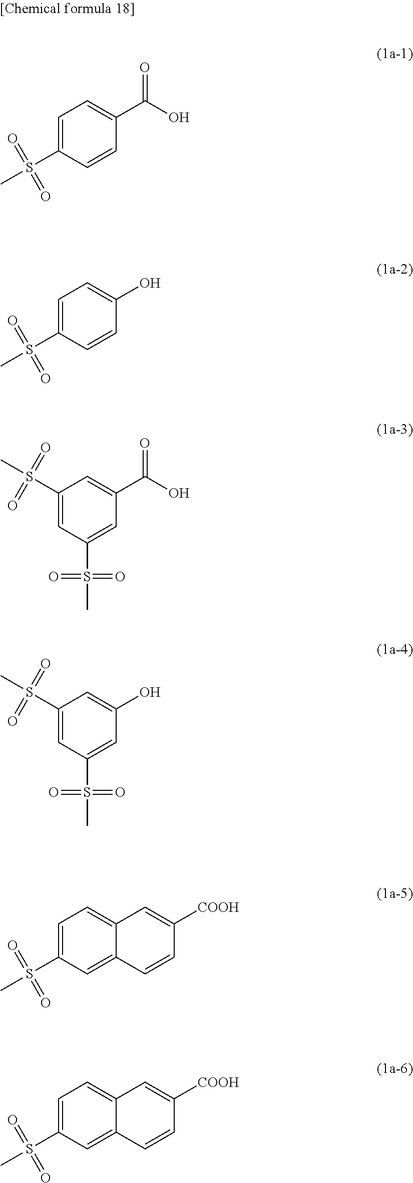 [SMILES: CS(=O)(=O)c1ccc(C(=O)O)cc1 ; CS(=O)(=O)c1ccc(O)cc1 ; CS(=O)(=O)c1cc(C(=O)O)cc(S(C)(=O)=O)c1 ; CS(=O)(=O)c1cc(O)cc(S(C)(=O)=O)c1 ; CS(=O)(=O)c1ccc2cc(C(=O)O)ccc2c1 ; CS(=O)(=O)c1ccc2cc(C(=O)O)ccc2c1]

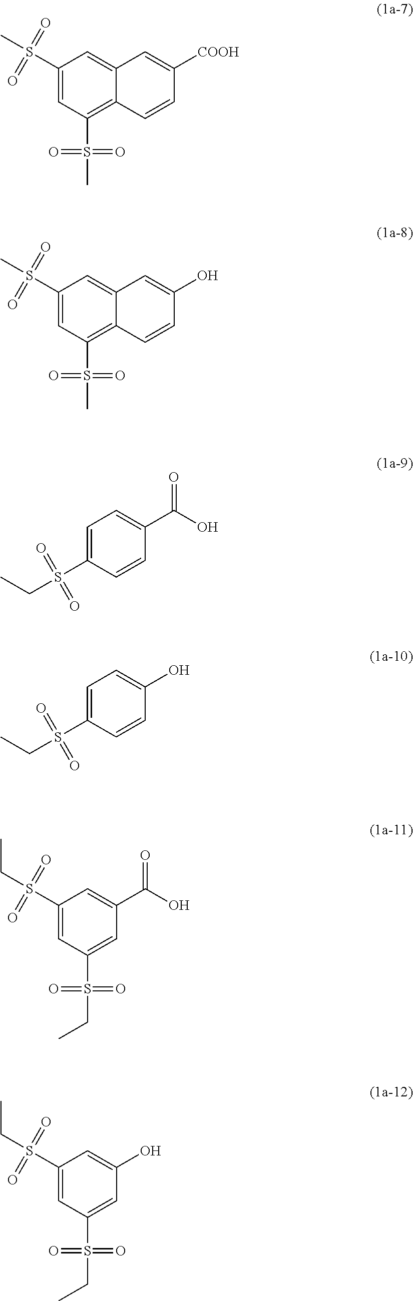 [SMILES: CS(=O)(=O)c1cc(S(C)(=O)=O)c2ccc(C(=O)O)cc2c1 ; CS(=O)(=O)c1cc(S(C)(=O)=O)c2ccc(O)cc2c1 ; CCS(=O)(=O)c1ccc(C(=O)O)cc1 ; CCS(=O)(=O)c1ccc(O)cc1 ; CCS(=O)(=O)c1cc(C(=O)O)cc(S(=O)(=O)CC)c1 ; CCS(=O)(=O)c1cc(O)cc(S(=O)(=O)CC)c1]

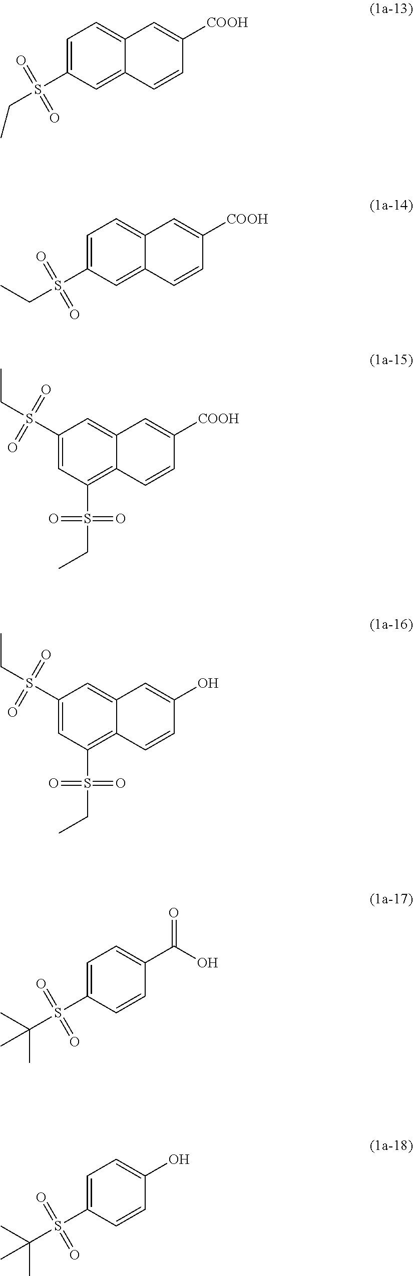 [SMILES: CCS(=O)(=O)c1ccc2cc(C(=O)O)ccc2c1 ; CCS(=O)(=O)c1ccc2cc(C(=O)O)ccc2c1 ; CCS(=O)(=O)c1cc(S(=O)(=O)CC)c2ccc(C(=O)O)cc2c1 ; CCS(=O)(=O)c1cc(S(=O)(=O)CC)c2ccc(O)cc2c1 ; CC(C)(C)S(=O)(=O)c1ccc(C(=O)O)cc1 ; CC(C)(C)S(=O)(=O)c1ccc(O)cc1]

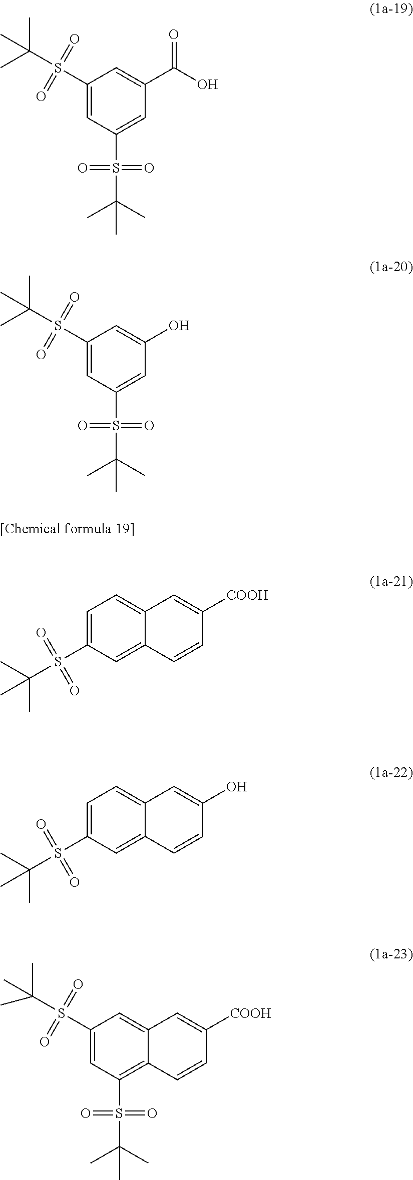 [SMILES: CC(C)(C)S(=O)(=O)c1cc(C(=O)O)cc(S(=O)(=O)C(C)(C)C)c1 ; CC(C)(C)S(=O)(=O)c1cc(O)cc(S(=O)(=O)C(C)(C)C)c1 ; CC(C)(C)S(=O)(=O)c1ccc2cc(C(=O)O)ccc2c1 ; CC(C)(C)S(=O)(=O)c1ccc2cc(O)ccc2c1 ; CC(C)(C)S(=O)(=O)c1cc(S(=O)(=O)C(C)(C)C)c2ccc(C(=O)O)cc2c1]

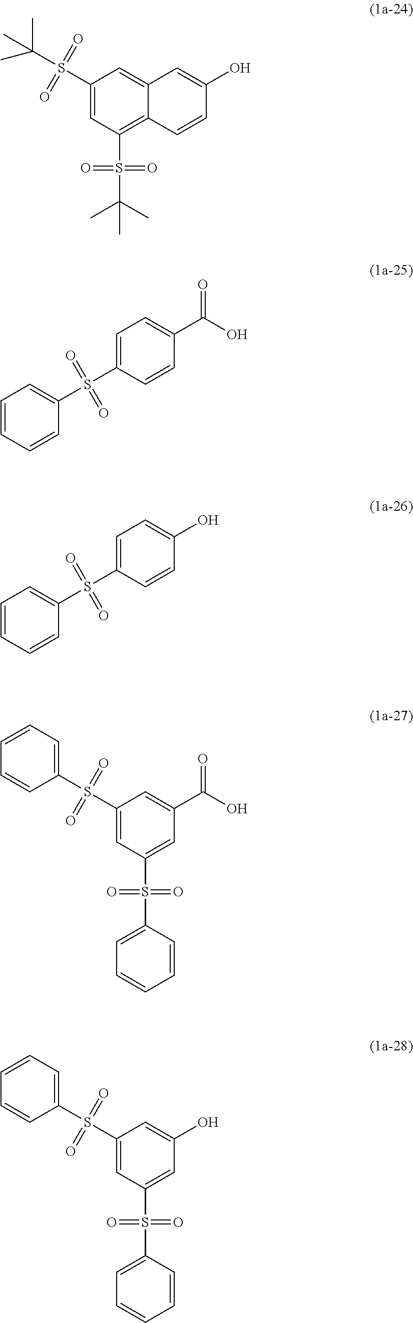 [SMILES: CC(C)(C)S(=O)(=O)c1cc(S(=O)(=O)C(C)(C)C)c2ccc(O)cc2c1 ; O=C(O)c1ccc(S(=O)(=O)c2ccccc2)cc1 ; O=S(=O)(c1ccccc1)c1ccc(O)cc1 ; O=C(O)c1cc(S(=O)(=O)c2ccccc2)cc(S(=O)(=O)c2ccccc2)c1 ; O=S(=O)(c1ccccc1)c1cc(O)cc(S(=O)(=O)c2ccccc2)c1]

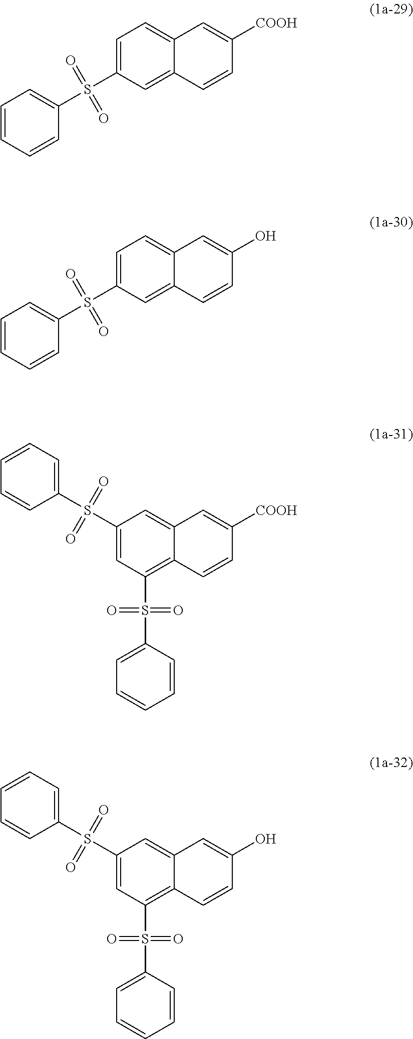 [SMILES: O=C(O)c1ccc2cc(S(=O)(=O)c3ccccc3)ccc2c1 ; O=S(=O)(c1ccccc1)c1ccc2cc(O)ccc2c1 ; O=C(O)c1ccc2c(S(=O)(=O)c3ccccc3)cc(S(=O)(=O)c3ccccc3)cc2c1 ; O=S(=O)(c1ccccc1)c1cc(S(=O)(=O)c2ccccc2)c2ccc(O)cc2c1]

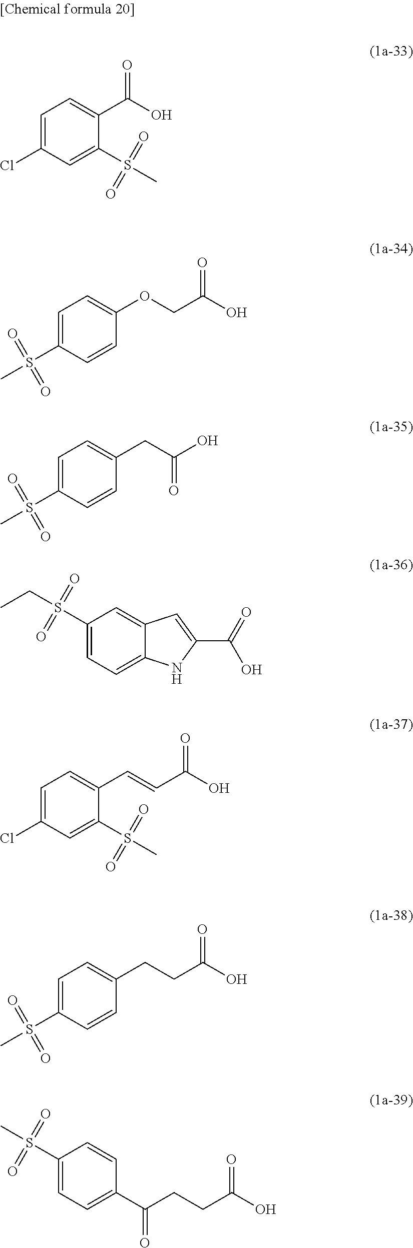

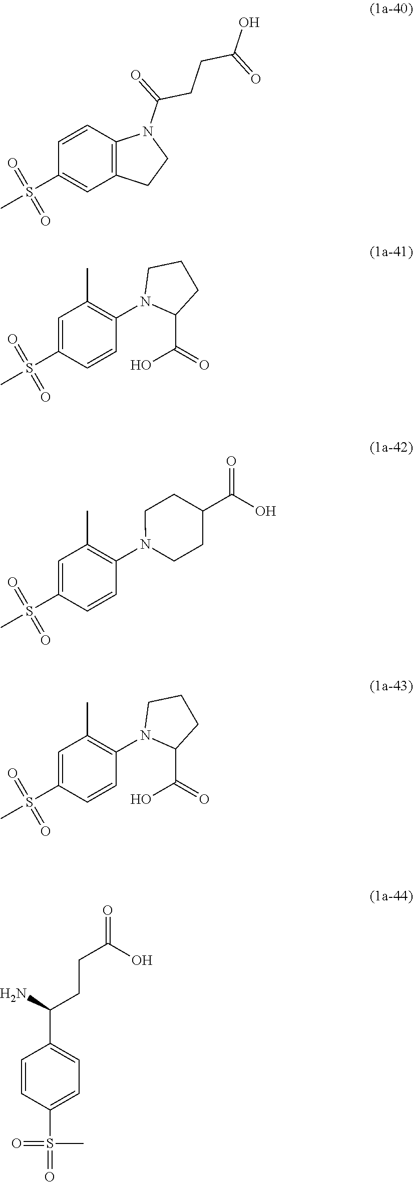 [SMILES: CS(=O)(=O)c1ccc2c(c1)CCN2C(=O)CCC(=O)O ; Cc1cc(S(C)(=O)=O)ccc1N1CCCC1C(=O)O ; Cc1cc(S(C)(=O)=O)ccc1N1CCC(C(=O)O)CC1 ; Cc1cc(S(C)(=O)=O)ccc1N1CCCC1C(=O)O ; CS(=O)(=O)c1ccc([C@@H](N)CCC(=O)O)cc1]

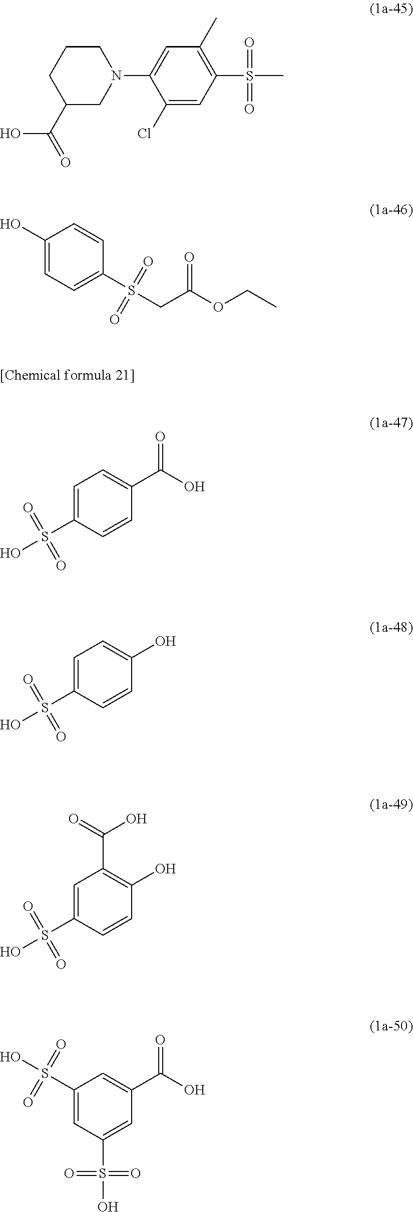 [SMILES: Cc1cc(N2CCCC(C(=O)O)C2)c(Cl)cc1S(C)(=O)=O ; CCOC(=O)CS(=O)(=O)c1ccc(O)cc1 ; O=C(O)c1ccc(S(=O)(=O)O)cc1 ; O=S(=O)(O)c1ccc(O)cc1 ; O=C(O)c1cc(S(=O)(=O)O)ccc1O ; O=C(O)c1cc(S(=O)(=O)O)cc(S(=O)(=O)O)c1]

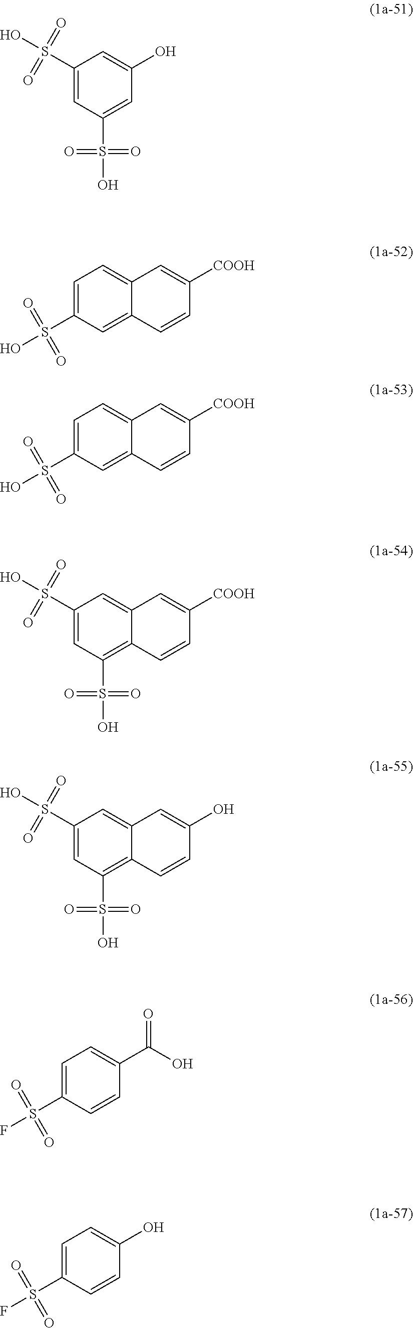

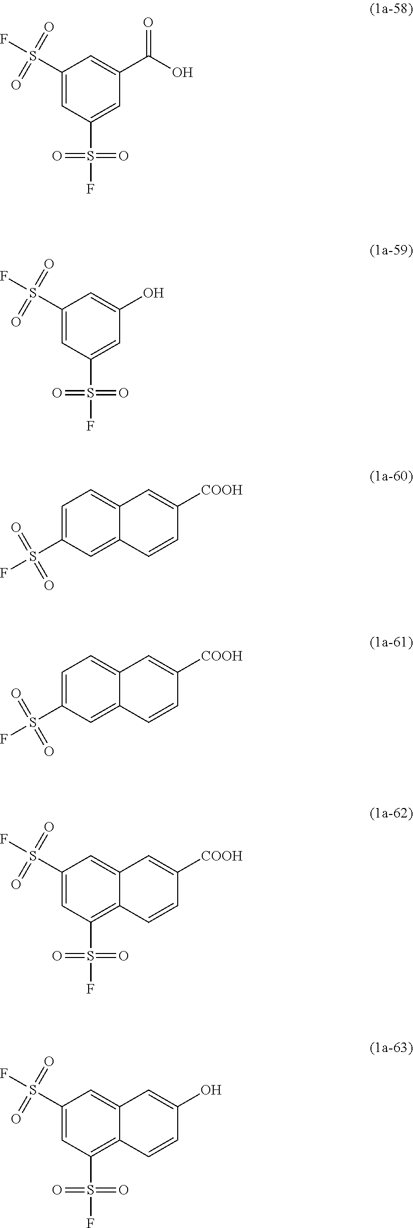 [SMILES: O=C(O)c1cc(S(=O)(=O)F)cc(S(=O)(=O)F)c1 ; O=S(=O)(F)c1cc(O)cc(S(=O)(=O)F)c1 ; O=C(O)c1ccc2cc(S(=O)(=O)F)ccc2c1 ; O=C(O)c1ccc2cc(S(=O)(=O)F)ccc2c1 ; O=C(O)c1ccc2c(S(=O)(=O)F)cc(S(=O)(=O)F)cc2c1 ; O=S(=O)(F)c1cc(S(=O)(=O)F)c2ccc(O)cc2c1]

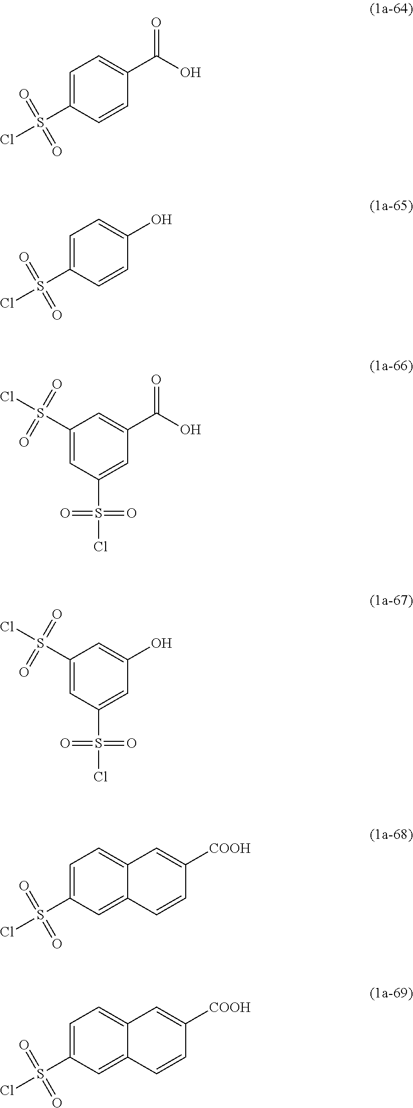 [SMILES: O=C(O)c1ccc(S(=O)(=O)Cl)cc1 ; O=S(=O)(Cl)c1ccc(O)cc1 ; O=C(O)c1cc(S(=O)(=O)Cl)cc(S(=O)(=O)Cl)c1 ; O=S(=O)(Cl)c1cc(O)cc(S(=O)(=O)Cl)c1 ; O=C(O)c1ccc2cc(S(=O)(=O)Cl)ccc2c1 ; O=C(O)c1ccc2cc(S(=O)(=O)Cl)ccc2c1]

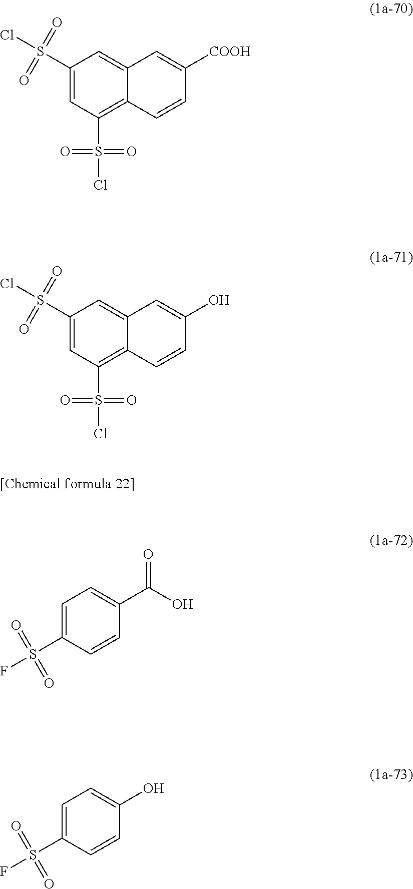 [SMILES: O=C(O)c1ccc2c(S(=O)(=O)Cl)cc(S(=O)(=O)Cl)cc2c1 ; O=S(=O)(Cl)c1cc(S(=O)(=O)Cl)c2ccc(O)cc2c1 ; O=C(O)c1ccc(S(=O)(=O)F)cc1 ; O=S(=O)(F)c1ccc(O)cc1]

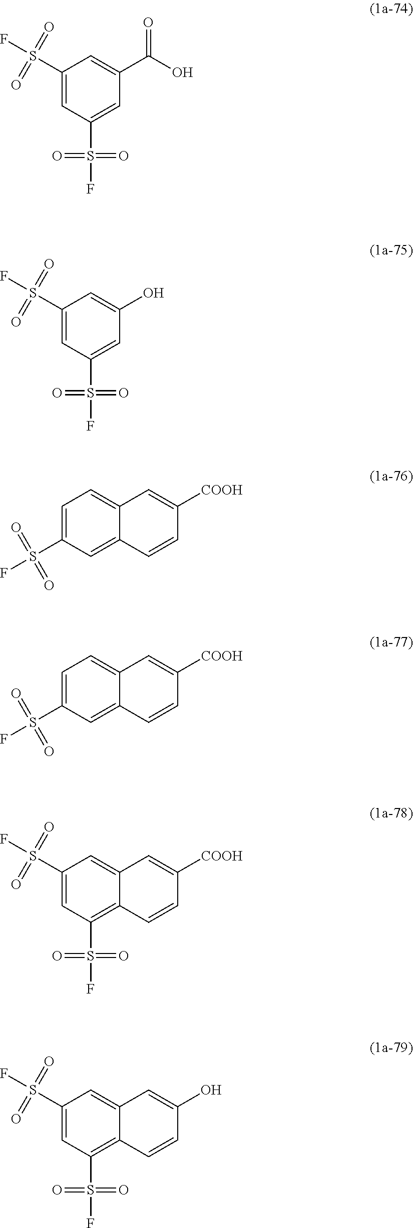 [SMILES: O=C(O)c1cc(S(=O)(=O)F)cc(S(=O)(=O)F)c1 ; O=S(=O)(F)c1cc(O)cc(S(=O)(=O)F)c1 ; O=C(O)c1ccc2cc(S(=O)(=O)F)ccc2c1 ; O=C(O)c1ccc2cc(S(=O)(=O)F)ccc2c1 ; O=C(O)c1ccc2c(S(=O)(=O)F)cc(S(=O)(=O)F)cc2c1 ; O=S(=O)(F)c1cc(S(=O)(=O)F)c2ccc(O)cc2c1]

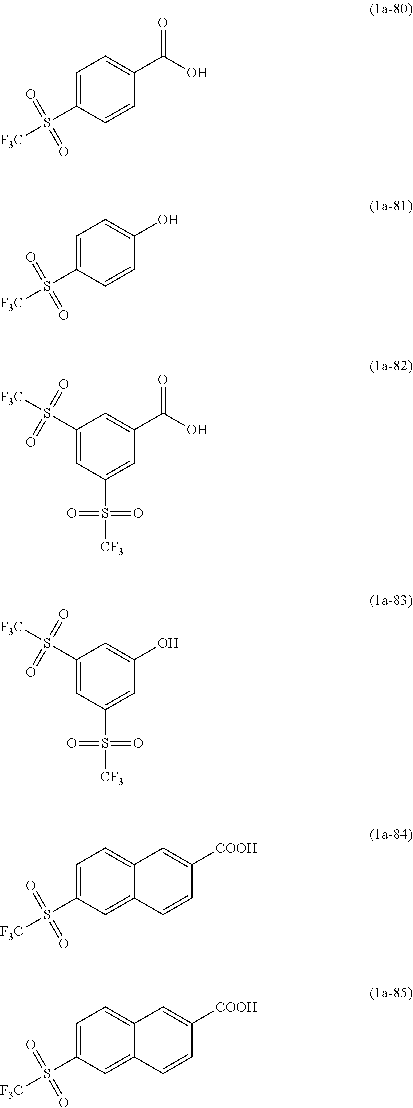 [SMILES: O=C(O)c1ccc(S(=O)(=O)C(F)(F)F)cc1 ; O=S(=O)(c1ccc(O)cc1)C(F)(F)F ; O=C(O)c1cc(S(=O)(=O)C(F)(F)F)cc(S(=O)(=O)C(F)(F)F)c1 ; O=S(=O)(c1cc(O)cc(S(=O)(=O)C(F)(F)F)c1)C(F)(F)F ; O=C(O)c1ccc2cc(S(=O)(=O)C(F)(F)F)ccc2c1 ; O=C(O)c1ccc2cc(S(=O)(=O)C(F)(F)F)ccc2c1]

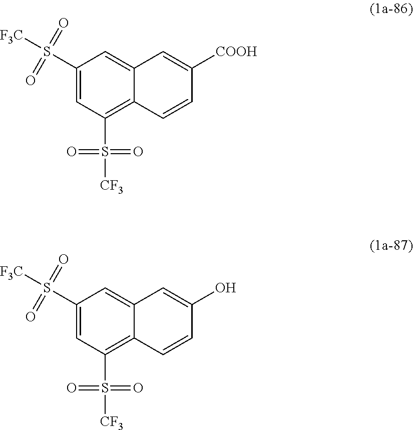 [SMILES: O=C(O)c1ccc2c(S(=O)(=O)C(F)(F)F)cc(S(=O)(=O)C(F)(F)F)cc2c1 ; O=S(=O)(c1cc(S(=O)(=O)C(F)(F)F)c2ccc(O)cc2c1)C(F)(F)F]

Examples of the compound represented by formula (2a) include compounds represented by the following formulae.

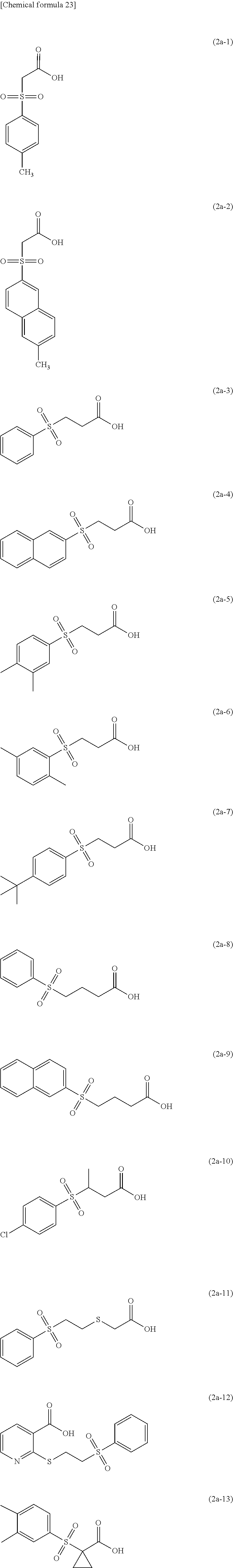

Compound (C) may be a compound disclosed in WO 2020/071361, which is represented by the following formula (1-1):

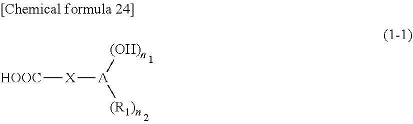

wherein X is a divalent organic group; A is an aryl group having 6 to 40 carbon atoms; R₁ is a halogen atom, an alkyl group having 1 to 40 carbon atoms, or an alkoxy group having 1 to 40 carbon atoms; n1 is an integer of 1 to 12; and n2 is an integer of 0 to 11.

The carboxy group in formula (1-1) may be replaced by a hydroxy group, an acyl group, an acetyl group, a formyl group, a benzoyl group, a carboxy group, a carbonyl group, an amino group, an imino group, a cyano group, an azo group, an azi group, a thiol group, a sulfo group, or an allyl group.

Specific examples of the above-mentioned X include an ester linkage, an ether linkage, an amide linkage, a urethane linkage, and a urea linkage, and, of these, preferred is an ester linkage or an ether linkage.

Specific examples of the above-mentioned A include a group derived from benzene, naphthalene, anthracene, phenanthrene, or pyrene, and, of these, preferred is a group derived from benzene, naphthalene, or anthracene.

Examples of the halogen atoms include a fluorine atom, a chlorine atom, a bromine atom, and an iodine atom.

Specific examples of the alkyl groups having 1 to 10 carbon atoms include a methyl group, an ethyl group, a propyl group, a butyl group, a hexyl group, and a pentyl group, and, of these, preferred is a methyl group.

Specific examples of the alkoxy groups having 1 to 10 carbon atoms include a methoxy group, an ethoxy group, a propoxy group, a butoxy group, a hexyl group, and a pentoxy group, and, of these, preferred is a methoxy group.

The expression “optionally substituted” means that part of or all of hydrogen atoms of the alkyl group having 1 to 10 carbon atoms are optionally replaced by, for example, a fluoro group or a hydroxy group.

Specific examples of the alkyl groups having 1 to 10 carbon atoms include a methyl group, an ethyl group, a propyl group, a butyl group, a hexyl group, and a pentyl group, and preferred is a methyl group.

The aryl group having 6 to 40 carbon atoms is as described above, and especially, a phenyl group is preferred.

Each of n1 and n3 is independently an integer of 1 to 12, but preferably an integer of 1 to 6.

n2 is an integer of 0 to 11, but preferably an integer of 0 to 2.

In formula (1-1), n2 is preferably 0.

Specific examples of the compounds represented by formula (1-1) include the below-shown compounds. The carboxy group of the below-shown compounds may be replaced by a hydroxy group, an acyl group, an acetyl group, a formyl group, a benzoyl group, a carboxy group, a carbonyl group, an amino group, an imino group, a cyano group, an azo group, an azi group, a thiol group, a sulfo group, or an allyl group.

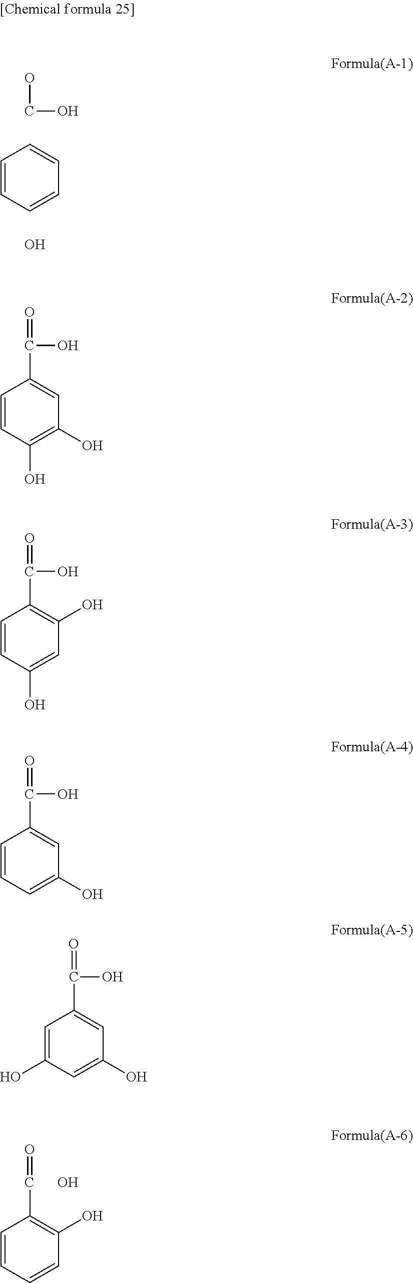

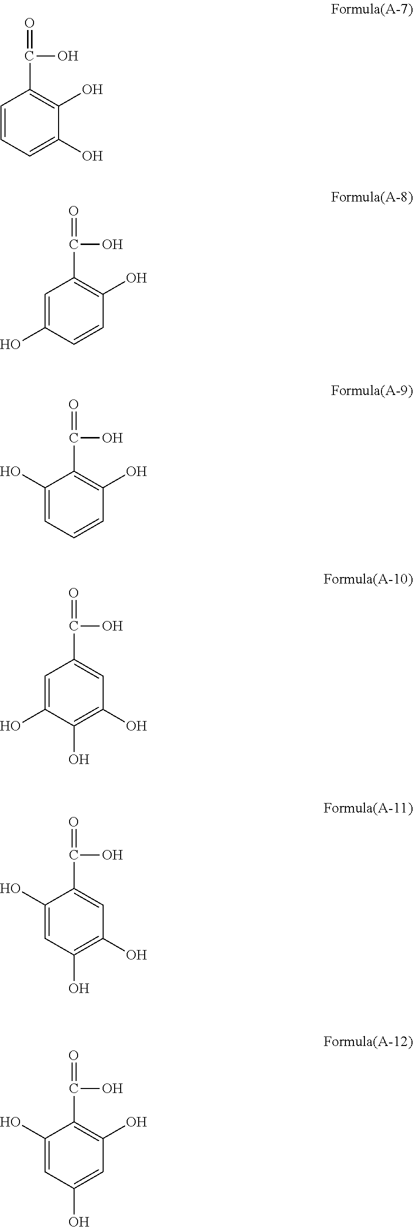 [SMILES: O=C(O)c1cccc(O)c1O ; O=C(O)c1cc(O)ccc1O ; O=C(O)c1c(O)cccc1O ; O=C(O)c1cc(O)c(O)c(O)c1 ; O=C(O)c1cc(O)c(O)cc1O ; O=C(O)c1c(O)cc(O)cc1O]

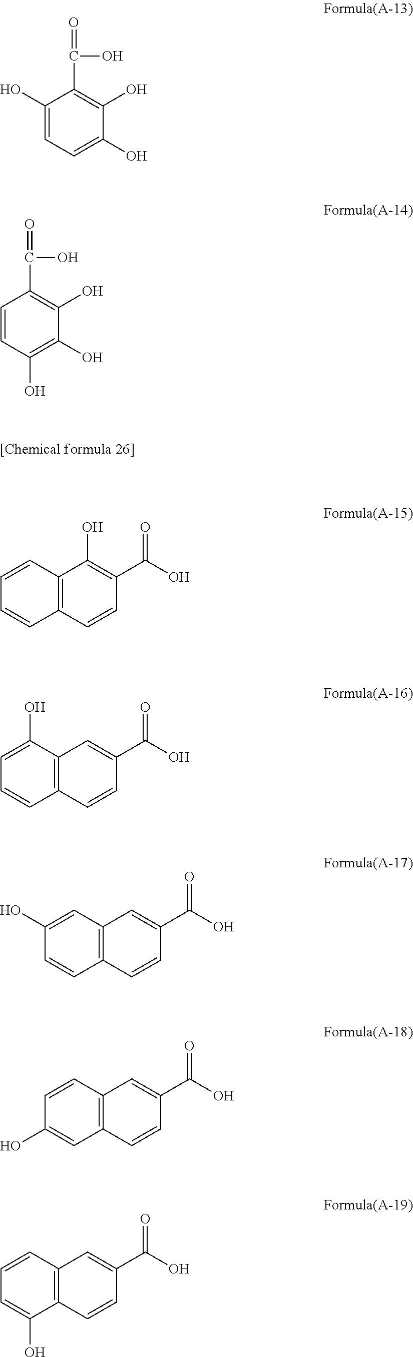

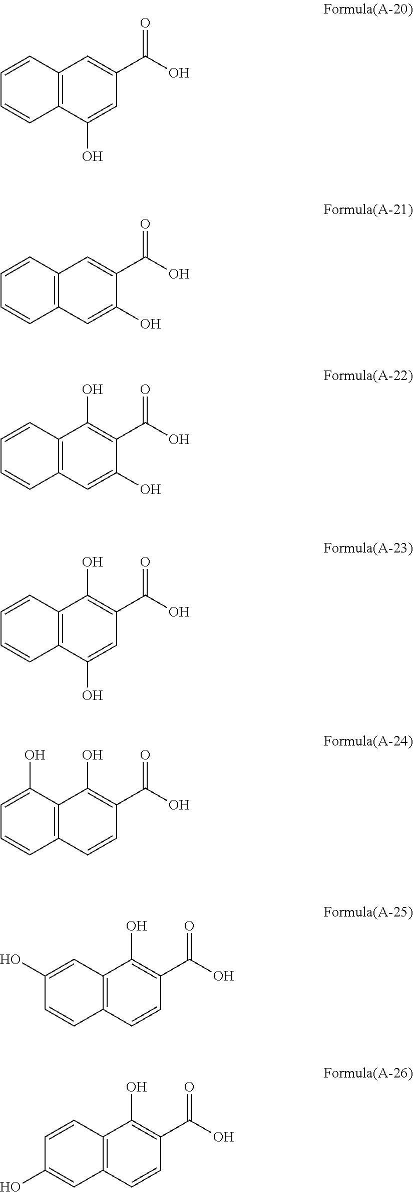

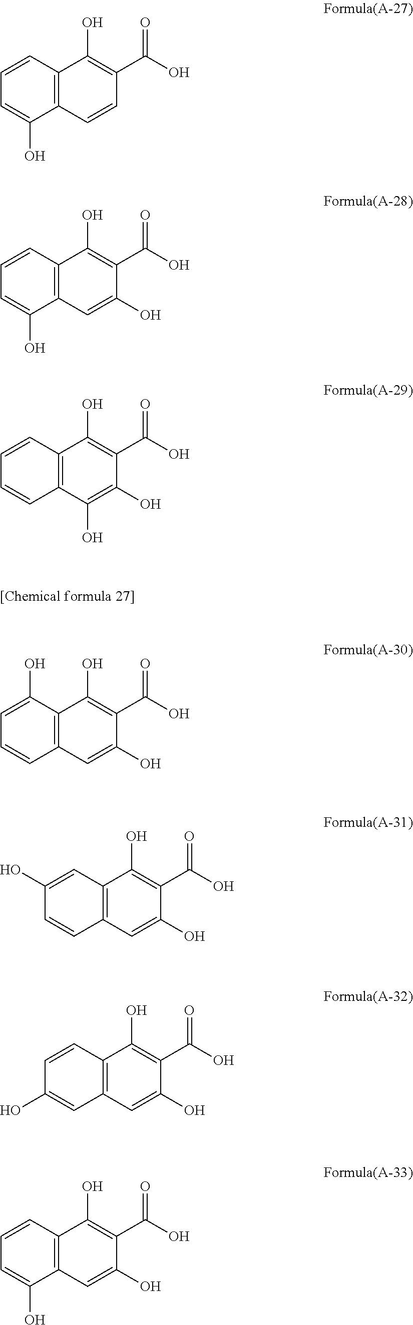

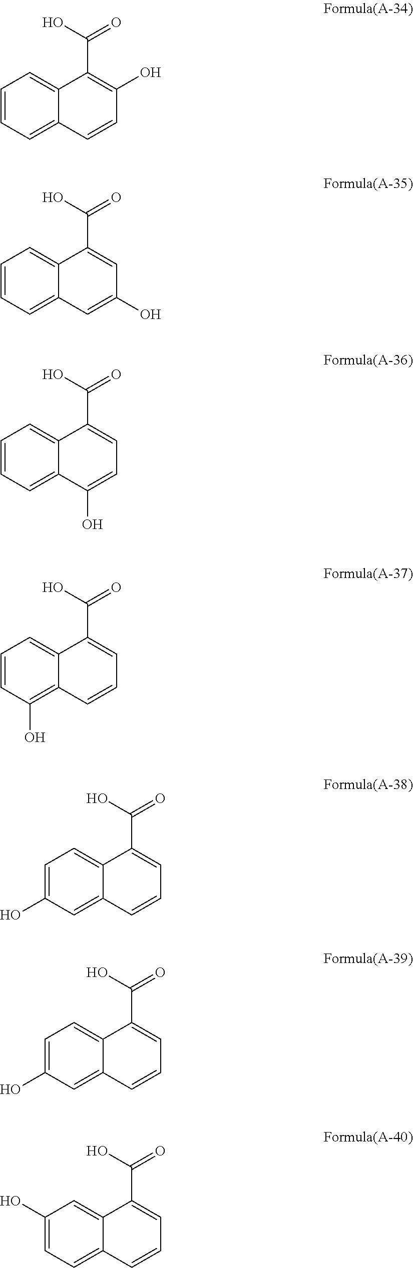

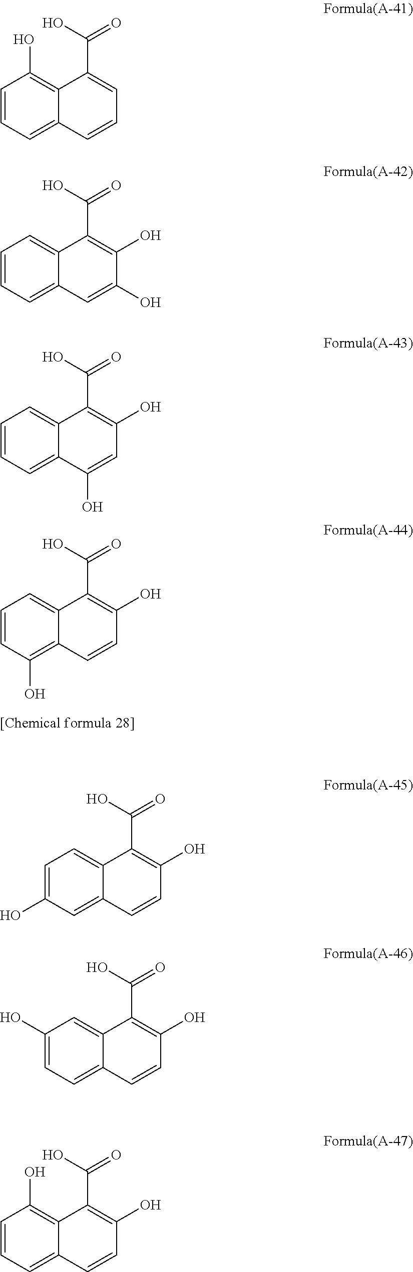

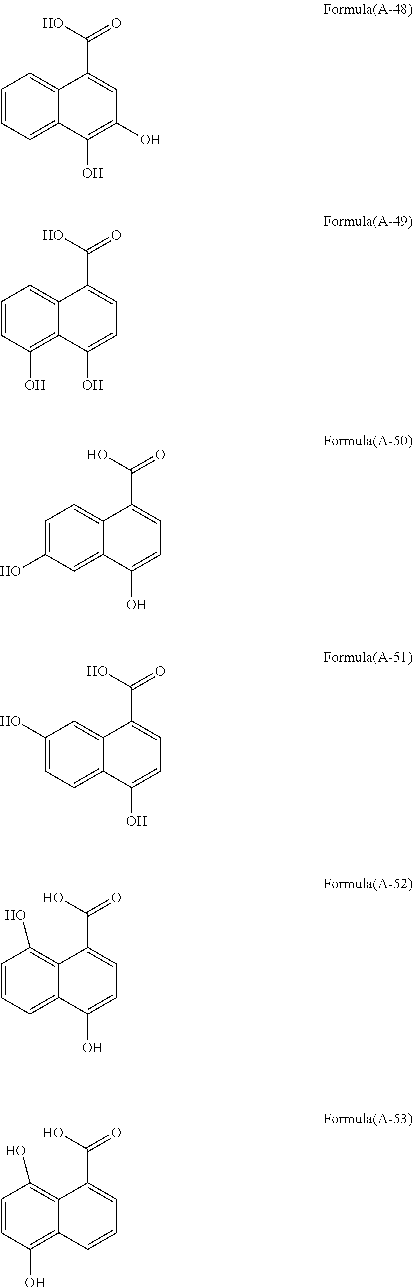 [SMILES: O=C(O)c1cc(O)c(O)c2ccccc12 ; O=C(O)c1ccc(O)c2c(O)cccc12 ; O=C(O)c1ccc(O)c2cc(O)ccc12 ; O=C(O)c1ccc(O)c2ccc(O)cc12 ; O=C(O)c1ccc(O)c2cccc(O)c12 ; O=C(O)c1cccc2c(O)ccc(O)c12]

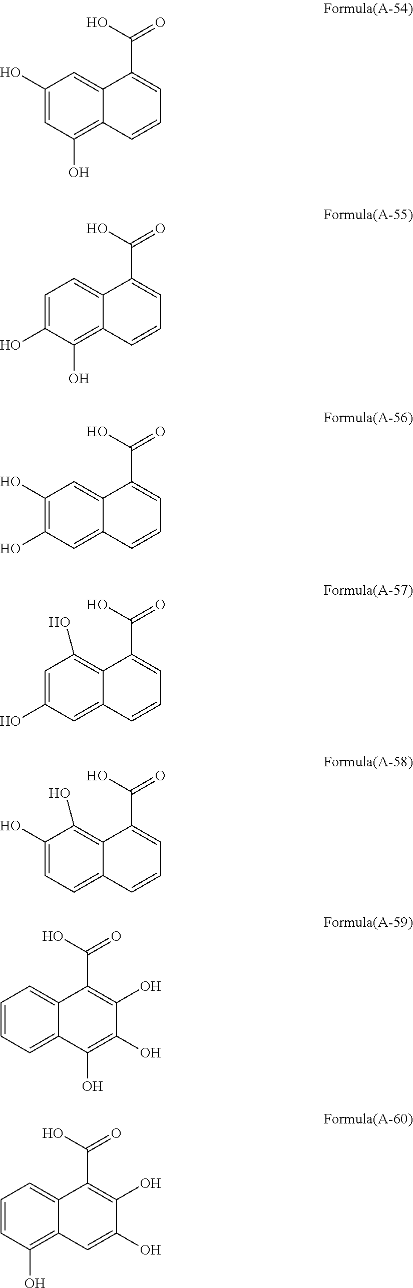

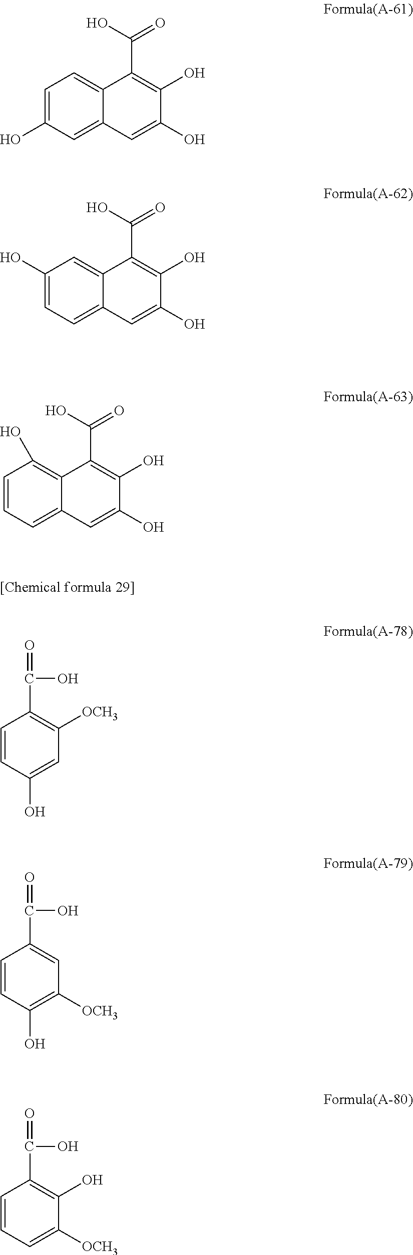 [SMILES: O=C(O)c1c(O)c(O)cc2cc(O)ccc12 ; O=C(O)c1c(O)c(O)cc2ccc(O)cc12 ; O=C(O)c1c(O)c(O)cc2cccc(O)c12 ; COc1cc(O)ccc1C(=O)O ; COc1cc(C(=O)O)ccc1O ; COc1cccc(C(=O)O)c1O]

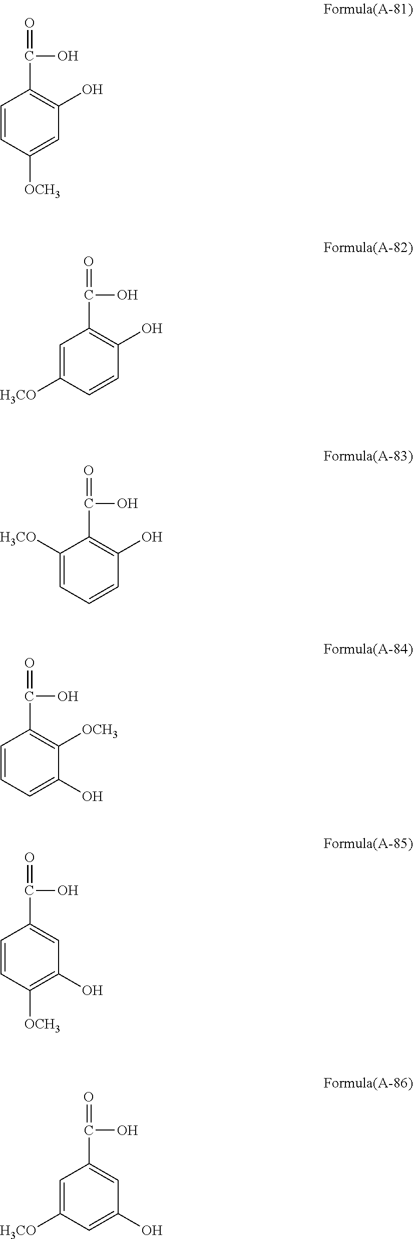 [SMILES: COc1ccc(C(=O)O)c(O)c1 ; COc1ccc(O)c(C(=O)O)c1 ; COc1cccc(O)c1C(=O)O ; COc1c(O)cccc1C(=O)O ; COc1ccc(C(=O)O)cc1O ; COc1cc(O)cc(C(=O)O)c1]

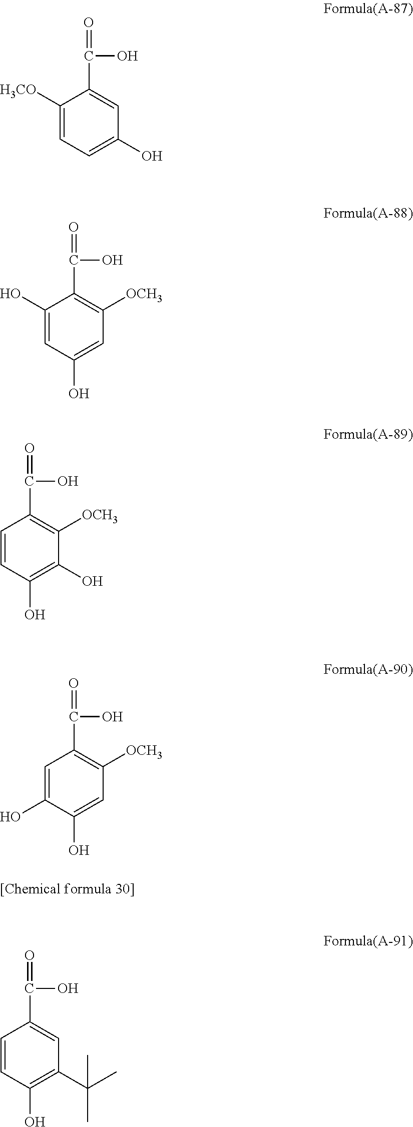

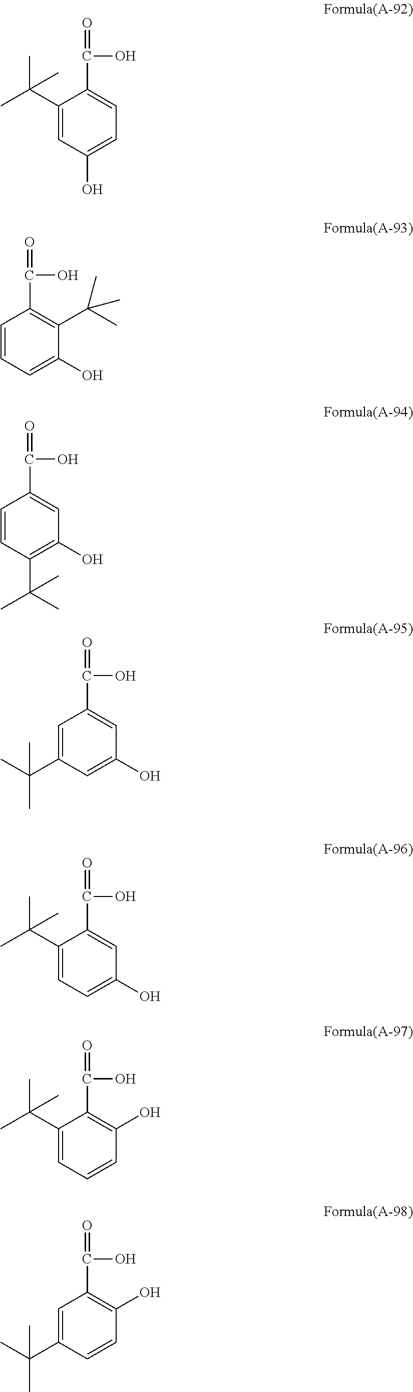

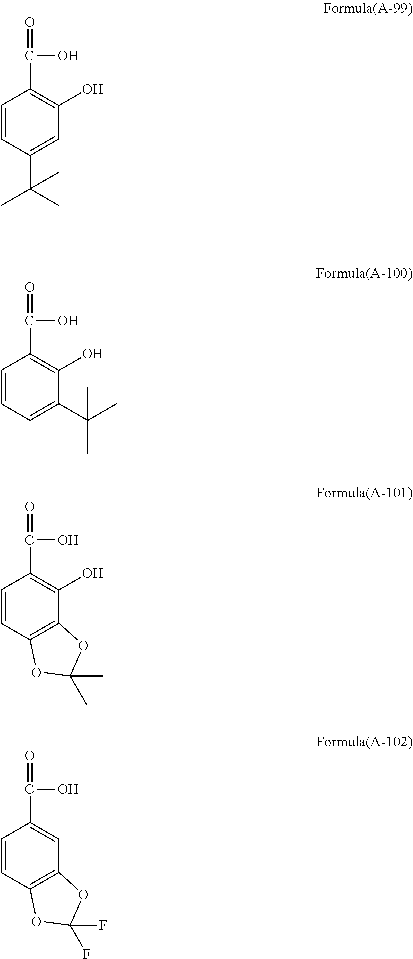

Compound (C) may be a compound disclosed in WO 2020/071361, which is represented by the following formula (2-1):

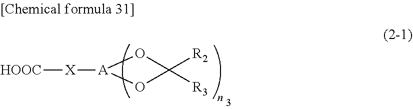

wherein X is a divalent organic group; A is an aryl group having 6 to 40 carbon atoms; each of R₂ and R₃ is independently a hydrogen atom, an optionally substituted alkyl group having 1 to 10 carbon atoms, an optionally substituted aryl group having 6 to 40 carbon atoms, or a halogen atom; and n3 is an integer of 1 to 12.

In formula (2-1), preferred X, A, R₂, R₃, and n3 in the present invention are as described above. In formula (2-1), R₂ and R₃ are preferably a hydrogen atom.

Specific examples of the compounds represented by formula (1-1) include the below-shown compounds. The carboxy group of the below-shown compounds may be replaced by a hydroxy group, an acyl group, an acetyl group, a formyl group, a benzoyl group, a carboxy group, a carbonyl group, an amino group, an imino group, a cyano group, an azo group, an azi group, a thiol group, a sulfo group, or an allyl group.

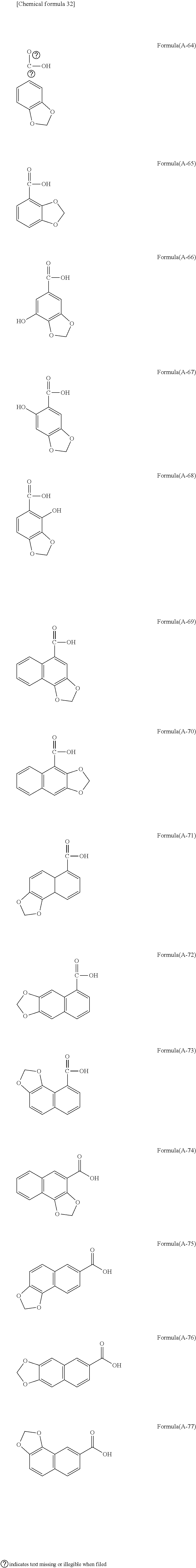

The entire disclosure of WO 2020/071361 is incorporated into the present application by reference.

### Solvent

With respect to the solvent used in the resist underlayer film-forming composition of the present invention, there is no particular limitation as long as it is a solvent which can uniformly dissolve therein a component that is in a solid state at ordinary room temperature, such as the above-mentioned reaction product, but preferred is an organic solvent generally used in a chemical liquid for semiconductor lithography process. Specific examples of solvents include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents may be used each alone or in combination of two or more thereof.

Of these solvents, propylene glycol monomethyl ether, propylene glycol monomethyl ether acetate, ethyl lactate, butyl lactate, and cyclohexanone are preferred. Especially preferred are propylene glycol monomethyl ether and propylene glycol monomethyl ether acetate.

### Acid Generator

With respect to the acid generator contained as an optional component in the resist underlayer film-forming composition of the present invention, any of a thermal acid generator and a photo-acid generator may be used, but a thermal acid generator is preferably used. Examples of thermal acid generators include sulfonic acid compounds and carboxyic acid compounds, such as p-toluenesulfonic acid, trifluoromethanesulfonic acid, pyridinium p-toluenesulfonate, pyridinium phenolsulfonate, pyridinium p-hydroxybenzenesulfonate (pyridinium p-phenolsulfonate), pyridinium trifluoromethanesulfonate, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photo-acid generators include an onium salt compound, a sulfonimide compound, and a disulfonyldiazomethane compound.

Examples of onium salt compounds include iodonium salt compounds, such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds, such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of sulfonimide compounds include N-(trifluoromethanesulfonyloxy)succinimide, N-(nonafluoronormalbutanesulfonyloxy)succinimide, N-(camphorsulfonyloxy)succinimide, and N-(trifluoromethanesulfonyloxy)naphthalimide.

Examples of disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more thereof.

When the acid generator is used, the amount of the acid generator contained is, for example, within the range of 0.1 to 50% by mass, preferably 1 to 30% by mass, based on the mass of the below-mentioned crosslinking agent.

### Crosslinking Agent

Examples of the crosslinking agent contained as an optional component in the resist underlayer film-forming composition of the present invention include hexamethoxymethylmelamine, tetramethoxymethylbenzoguanamine, 1,3,4,6-tetrakis(methoxymethyl)glycoluril (tetramethoxymethylglycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

Further, the crosslinking agent in the present invention may be a nitrogen-containing compound disclosed in WO 2017/187969 having per molecule 2 to 6 substituents bonded to a nitrogen atom represented by the following formula (1d):

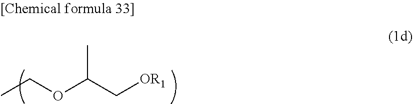

wherein R₁ represents a methyl group or an ethyl group.

The nitrogen-containing compound having 2 to 6 substituents represented by formula (1d) above per molecule may be a glycoluril derivative represented by the following formula (1E):

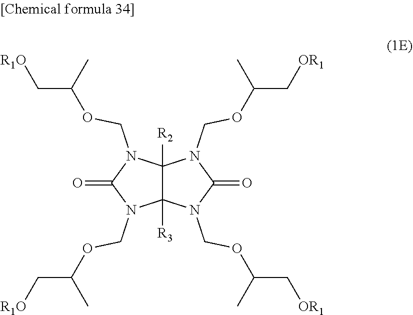

wherein each of four R₁'s independently represents a methyl group or an ethyl group, and each of R₂ and R₃ independently represents a hydrogen atom, an alkyl group having 1 to 4 carbon atoms, or a phenyl group.

Examples of the glycoluril derivative represented by formula (1E) include compounds represented by the following formulae (1E-1) to (1E-6).

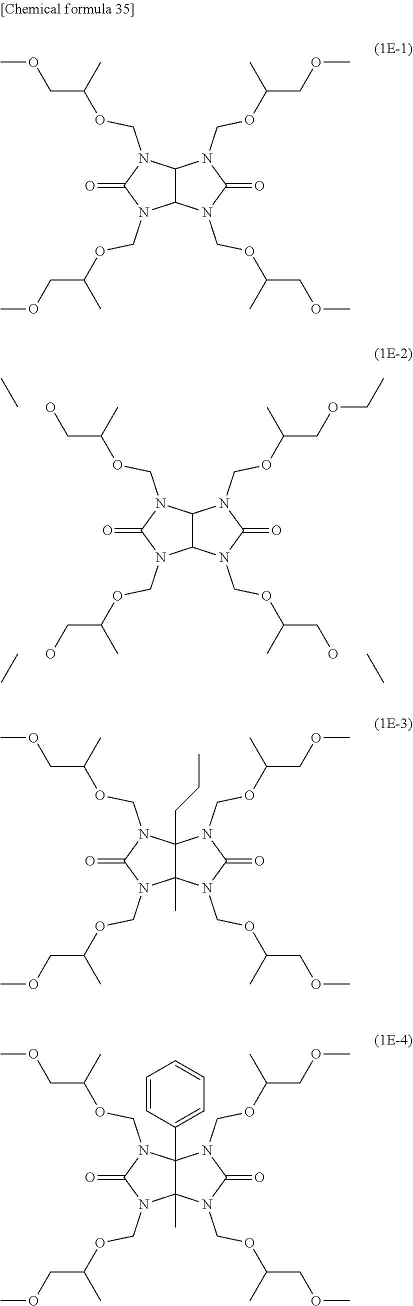

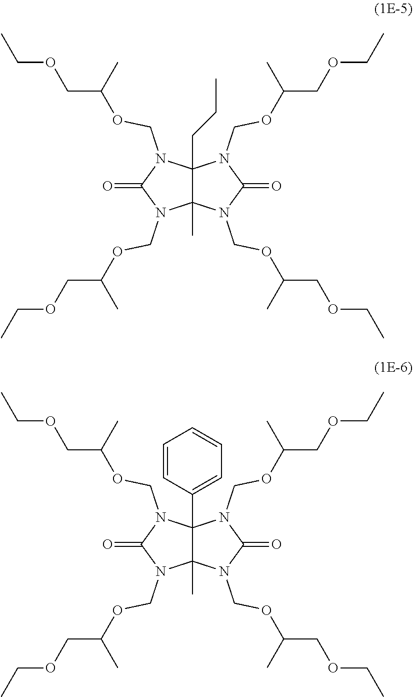

The nitrogen-containing compound having 2 to 6 substituents represented by formula (1d) per molecule may be obtained by reacting a nitrogen-containing compound having per molecule 2 to 6 substituents bonded to a nitrogen atom represented by the following formula (2d), and at least one compound represented by the following formula (3d):

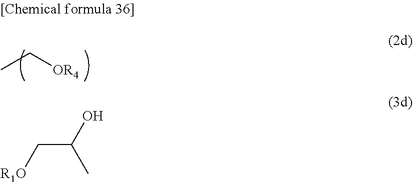

wherein, in formulae (2d) and (3d), R₁ represents a methyl group or an ethyl group; and R₄ represents an alkyl group having 1 to 4 carbon atoms.

The glycoluril derivative represented by formula (1E) may be obtained by reacting a glycoluril derivative represented by formula (2E) below and at least one compound represented by formula (3d) above.

The nitrogen-containing compound having 2 to 6 substituents represented by formula (2d) above per molecule is, for example, a glycoluril derivative represented by the following formula (2E):

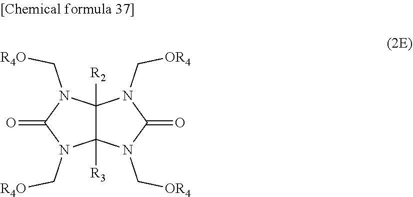

wherein each of R₂ and R₃ independently represents a hydrogen atom, an alkyl group having 1 to 4 carbon atoms, or a phenyl group; and each R₄ independently represents an alkyl group having 1 to 4 carbon atoms.

Examples of the glycoluril derivative represented by formula (2E) include compounds represented by the following formulae (2E-1) to (2E-4). Further, examples of the compound represented by formula (3d) include compounds represented by the following formulae (3d-1) and (3d-2).

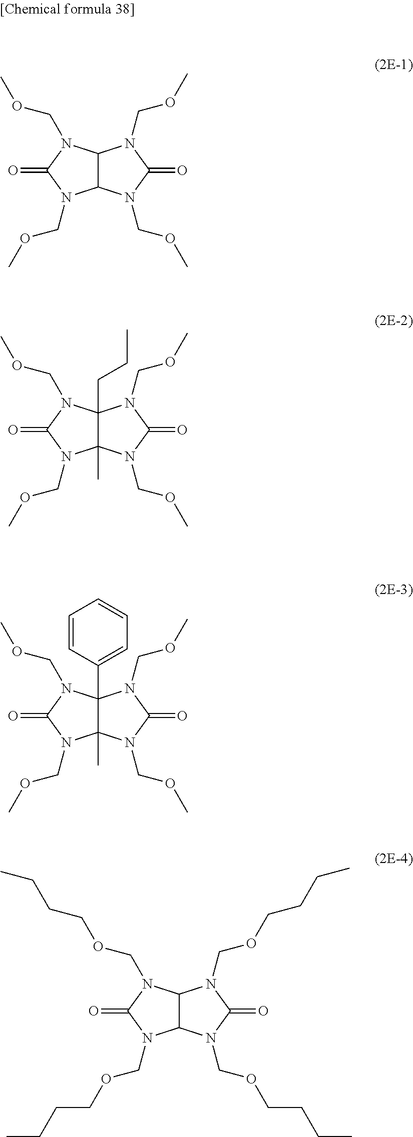

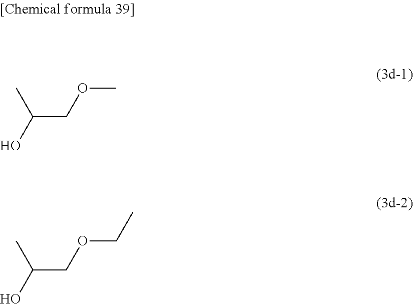

With respect to the nitrogen-containing compound having per molecule 2 to 6 substituents bonded to a nitrogen atom represented by formula (1d), the disclosure of WO 2017/187969 in its corresponding parts is incorporated into the present application by reference.

When the crosslinking agent is used, the amount of the crosslinking agent contained is, for example, within the range of 1 to 50% by mass, preferably 5 to 30% by mass, based on the mass of the reaction product.

### Other Components

In the resist underlayer film-forming composition of the present invention, for further improving the application properties to prevent the occurrence of pinhole or striation and uneven surface, a surfactant may be further added to the composition. Examples of surfactants include nonionic surfactants, e.g., polyoxyethylene alkyl ethers, such as polyoxyethylene lauryl ether, polyoxyethylene stearyl ether, polyoxyethylene cetyl ether, and polyoxyethylene oleyl ether; polyoxyethylene alkyl aryl ethers, such as polyoxyethylene octylphenol ether and polyoxyethylene nonylphenol ether; polyoxyethylene-polyoxypropylene block copolymers; sorbitan fatty acid esters, such as sorbitan monolaurate, sorbitan monopalmitate, sorbitan monostearate, sorbitan monooleate, sorbitan trioleate, and sorbitan tristearate; and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, fluorine surfactants, such as EFTOP EF301, EF303, EF352 (trade name, manufactured by Tohchem Products Co., Ltd.), MEGAFACE F171, F173, R-30 (trade name, manufactured by DIC Corporation), Fluorad FC430, FC431 (trade name, manufactured by Sumitomo 3M), AsahiGuard AG710, Surflon S-382, SC101, SC102, SC103, SC104, SC105, SC106 (trade name, manufactured by AGC Inc.), and organosiloxane polymer KP341 (manufactured by Shin-Etsu Chemical Co., Ltd.). The amount of the surfactant incorporated is generally 2.0% by mass or less, preferably 1.0% by mass or less, based on the mass of the solids of the resist underlayer film-forming composition of the present invention. These surfactants may be used each alone or in combination of two or more thereof.

The solid content of the resist underlayer film-forming composition of the present invention, i.e., the content of the components except the solvent in the composition is, for example, within the range of 0.01 to 10% by mass.

### Resist Underlayer Film

The resist underlayer film of the present invention may be produced by applying the above-described resist underlayer film-forming composition onto a semiconductor substrate and baking the applied composition.

Examples of semiconductor substrates to which the resist underlayer film-forming composition of the present invention is applied include a silicon wafer, a germanium wafer, and compound semiconductor wafers, such as gallium arsenide, indium phosphide, gallium nitride, indium nitride, and aluminum nitride.

When a semiconductor substrate having an inorganic film formed on the surface thereof is used, the inorganic film is formed by, for example, an ALD (atomic layer deposition) method, a CVD (chemical vapor deposition) method, a reactive sputtering method, an ion plating method, a vacuum deposition method, or a spin coating method (spin on glass: SOG). Examples of the inorganic films include a polysilicon film, a silicon oxide film, a silicon nitride film, a BPSG (Boro-Phospho Silicate Glass) film, a titanium nitride film, a titanium nitride oxide film, a tungsten film, a gallium nitride film, and a gallium arsenide film.

The resist underlayer film-forming composition of the present invention is applied onto the above-mentioned semiconductor substrate by an appropriate application method, such as a spinner or a coater. Then, the applied composition is baked using a heating means, such as a hotplate, to form a resist underlayer film. Conditions for baking are appropriately selected from those at a baking temperature of 100 to 400° C. for a baking time of 0.3 to 60 minutes. Preferred conditions for baking are those at a baking temperature of 120 to 350° C. for a baking time of 0.5 to 30 minutes, and more preferred conditions are those at a baking temperature of 150 to 300° C. for a baking time of 0.8 to 10 minutes.

The thickness of the formed resist underlayer film is, for example, within the range of 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (1 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), or 0.005 μm (5 nm) to 0.02 μm (20 nm). When the temperature for baking is lower than the above-mentioned range, crosslinking becomes unsatisfactory. On the other hand, when the temperature for baking is higher than the above-mentioned range, the resist underlayer film is likely to be decomposed due to heat.

### Method for Producing a Patterned Substrate and Method for Producing a Semiconductor Device

The method for producing a patterned substrate comprises the steps described below. Generally, a patterned substrate is produced by forming a photoresist layer on a resist underlayer film. With respect to the photoresist formed on the resist underlayer film by applying and baking by a known method, there is no particular limitation as long as it is sensitive to a light used in the exposure. Any of a negative photoresist and a positive photoresist may be used. They include, for example, a positive photoresist comprising a novolak resin and 1,2-naphthoquinonediazidosulfonate; a chemical amplification photoresist comprising a binder having a group which is decomposed due to an acid to increase the alkali solubility and a photo-acid generator; a chemical amplification photoresist comprising a low-molecular weight compound which is decomposed due to an acid to increase the alkali solubility of the photoresist, an alkali-soluble binder, and a photo-acid generator; a chemical amplification photoresist comprising a binder having a group which is decomposed due to an acid to increase the alkali solubility, a low-molecular weight compound which is decomposed due to an acid to increase the alkali solubility of the photoresist, and a photo-acid generator; and a resist containing a metal element. For example, they include trade name: V146G, manufactured by JSR Corporation, trade name: APEX-E, manufactured by Shipley Company, Inc., trade name: PAR710, manufactured by Sumitomo Chemical Co., Ltd., and trade name: AR2772, SEPR430, manufactured by Shin-Etsu Chemical Co., Ltd. Further, they include fluorine atom-containing polymer photoresists described in, for example, Proc. SPIE, Vol. 3999, 330-334 (2000), Proc. SPIE, Vol. 3999, 357-364 (2000), and Proc. SPIE, Vol. 3999, 365-374 (2000).

Further, there may be used the resist composition, radiation-sensitive resin composition, the so-called resist composition, e.g., a high resolution patterning composition based on an organometal solution, and metal-containing resist composition, which are described in, for example, WO 2019/188595, WO 2019/187881, WO 2019/187803, WO 2019/167737, WO 2019/167725, WO 2019/187445, WO 2019/167419, WO 2019/123842, WO 2019/054282, WO 2019/058945, WO 2019/058890, WO 2019/039290, WO 2019/044259, WO 2019/044231, WO 2019/026549, WO 2018/193954, WO 2019/172054, WO 2019/021975, WO 2018/230334, WO 2018/194123, JP 2018-180525 A, WO 2018/190088, JP 2018-070596 A, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, and JP 2010-128369 A, WO 2018/031896, JP 2019-113855 A, WO 2017/156388, WO 2017/066319, JP 2018-41099 A, WO 2016/065120, WO 2015/026482, and JP 2016-29498 A and JP 2011-253185 A, but the resist is not limited to these compositions.

Examples of the resist compositions include the following compositions.

An active light-sensitive or radiation-sensitive resin composition, which comprises a resin A having a repeating unit having an acid decomposable group with a polar group protected by a protecting group capable of being eliminated by the action of an acid, and a compound represented by the general formula (21).

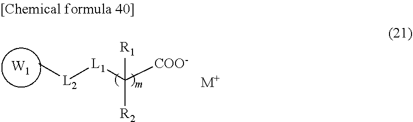

In the general formula (21), m represents an integer of 1 to 6.

Each of R₁ and R₂ independently represents a fluorine atom or a perfluoroalkyl group.

L₁ represents —O—, —S—, —COO—, —SO₂—, or —SO₃—.

L₂ represents an alkylene group optionally having a substituent, or a single bond.

W₁ represents a cyclic organic group optionally having a substituent.

M⁺ represents a cation.

A metal-containing film-forming composition for extreme ultraviolet light or electron beam lithography, which comprises a compound having a metal-oxygen covalent bond, and a solvent, wherein the metal element constituting the compound belongs to Periods 3 to 7 of Groups 3 to 15 of the periodic table.

A radiation-sensitive resin composition, which comprises a polymer having a first structural unit represented by the following formula (31) and a second structural unit represented by the following formula (32) which contains an acid dissociating group, and an acid generator:

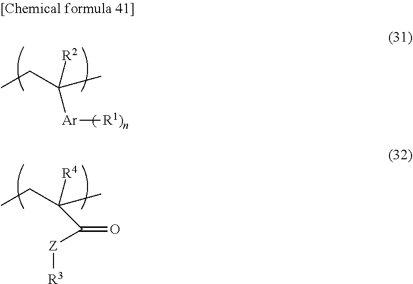

wherein, in formula (31), Ar is a group obtained by removing (n+1) hydrogen atoms from an arene having 6 to 20 carbon atoms; R¹ is a hydroxy group, a sulfanyl group, or a monovalent organic group having 1 to 20 carbon atoms; n is an integer of 0 to 11, wherein when n is 2 or more, two or more R¹'s are the same or different; and R² is a hydrogen atom, a fluorine atom, a methyl group, or a trifluoromethyl group; and, in formula (32), R³ is a monovalent group having 1 to 20 carbon atoms and containing the acid dissociating group; Z is a single bond, an oxygen atom, or a sulfur atom; and R⁴ is a hydrogen atom, a fluorine atom, a methyl group, or a trifluoromethyl group.

A resist composition, which comprises a resin (A1) containing a structural unit having a cyclic carbonate structure, a structural unit represented by formula (II), and a structural unit having an acid destabilizing group, and an acid generator:

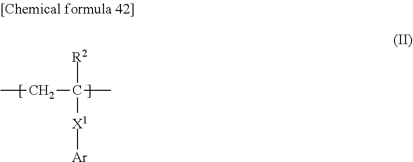

wherein R² represents an alkyl group having 1 to 6 carbon atoms and optionally having a halogen atom, a hydrogen atom, or a halogen atom; X¹ represents a single bond, —CO—O—*, or —CO—NR⁴—*, wherein * represents a bonding site with —Ar; and R⁴ represents a hydrogen atom or an alkyl group having 1 to 4 carbon atoms; and Ar represents an aromatic hydrocarbon group having 6 to 20 carbon atoms and optionally having at least one group selected from the group consisting of a hydroxy group and a carboxy group.

Examples of the resist films include the followings.

A resist film, which comprises a base resin having a repeating unit represented by the following formula (a1) and/or a repeating unit represented by the following formula (a2), and a repeating unit that generates an acid bonded to a polymer principal chain by exposure:

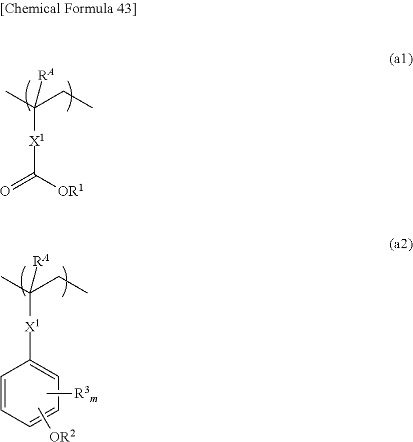

wherein, in formulae (a1) and (a2), each R^{A} is independently a hydrogen atom or a methyl group; each of R¹ and R² is independently a tertiary alkyl group having 4 to 6 carbon atoms; each R³ is independently a fluorine atom or a methyl group; m is an integer of 0 to 4; X¹ is a single bond, a phenylene group, a naphthylene group, or a linking group having 1 to 12 carbon atoms and containing at least one member selected from an ester linkage, a lactone ring, a phenylene group, and a naphthylene group; and X² is a single bond, an ester linkage, or an amide linkage.

Examples of the resist materials include the followings.

A resist material, which comprises a polymer having a repeating unit represented by the following formula (b1) or (b2):

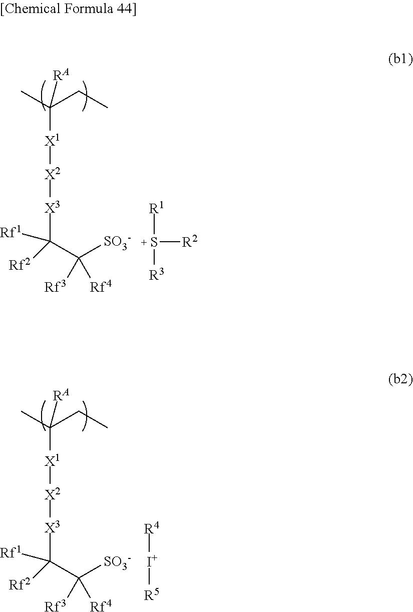

wherein, in formulae (b1) and (b2), R^{A} is a hydrogen atom or a methyl group; X¹ is a single bond or an ester group; X² is a linear, branched, or cyclic alkylene group having 1 to 12 carbon atoms or an arylene group having 6 to 10 carbon atoms, wherein part of the methylene group constituting the alkylene group is optionally substituted with an ether group, an ester group, or a lactone ring-containing group, and wherein at least one hydrogen atom contained in X² is replaced by a bromine atom; X³ is a single bond, an ether group, an ester group, or a linear, branched, or cyclic alkylene group having 1 to 12 carbon atoms, wherein part of the methylene group constituting the alkylene group is optionally substituted with an ether group or an ester group; each of Rf¹ to Rf⁴ is independently a hydrogen atom, a fluorine atom, or a trifluoromethyl group, wherein at least one of Rf¹ to Rf⁴ is a fluorine atom or a trifluoromethyl group, and wherein Rf¹ and Rf² are optionally bonded together to form a carbonyl group; each of R₁ to R⁵ is independently a linear, branched, or cyclic alkyl group having 1 to 12 carbon atoms, a linear, branched, or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, wherein part of or all of hydrogen atoms of the above groups are optionally replaced by a hydroxy group, a carboxy group, a halogen atom, an oxo group, a cyano group, an amido group, a nitro group, a sultone group, a sulfone group, or a sulfonium salt-containing group, wherein part of the methylene group constituting the above groups is optionally substituted with an ether group, an ester group, a carbonyl group, a carbonate group, or a sulfonate group, and wherein R₁ and R² are optionally bonded to form a ring, together with the sulfur atom to which R₁ and R² are bonded.

A resist material, which comprises a base resin containing a polymer having a repeating unit represented by the following formula (a):

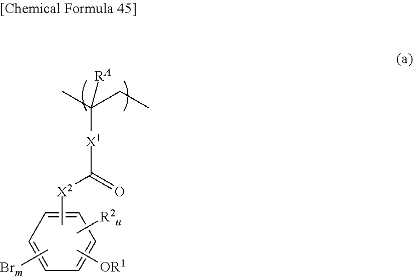

wherein R^{A} is a hydrogen atom or a methyl group; R¹ is a hydrogen atom or an acid destabilizing group; R² is a linear, branched, or cyclic alkyl group having 1 to 6 carbon atoms, or a halogen atom other than bromine; X¹ is a single bond, a phenylene group, or a linear, branched, or cyclic alkylene group having 1 to 12 carbon atoms and optionally having an ester group or a lactone ring; X² is —O—, —O—CH₂—, or —NH—; m is an integer of 1 to 4; and n is an integer of 0 to 3.

A resist composition, which generates an acid by exposure and changes in the solubility in a developer by the action of the acid, wherein the resist composition comprises a base component (A), which changes in the solubility in a developer by the action of an acid, and a fluorine additive component (F), which shows decomposability with respect to an alkaline developer, wherein the fluorine additive component (F) comprises a fluorine resin component (F1) having a constitutional unit (f1) containing a base-dissociating group and a constitutional unit (f2) containing a group represented by the following general formula (f2-r-1):

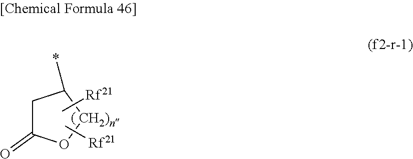

wherein each Rf²¹ is independently a hydrogen atom, an alkyl group, an alkoxy group, a hydroxy group, a hydroxyalkyl group, or a cyano group; n″ is an integer of 0 to 2; and * is a bonding site.

The above-mentioned constitutional unit (f1) contains a constitutional unit represented by the following general formula (f1-1) or a constitutional unit represented by the following general formula (f1-2):

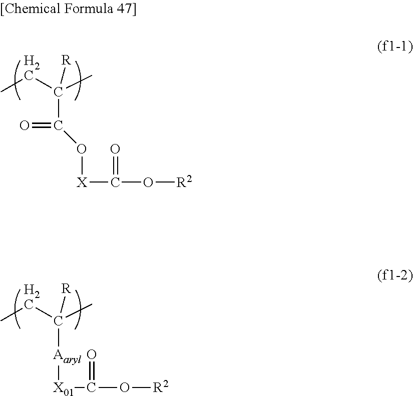

wherein each R is independently a hydrogen atom, an alkyl group having 1 to 5 carbon atoms, or a halogenated alkyl group having 1 to 5 carbon atoms; X is a divalent linking group having no acid-dissociating site; A_{aryl} is a divalent aromatic cyclic group optionally having a substituent; X₀₁ is a single bond or a divalent linking group; and each R² is independently an organic group having a fluorine atom.

Examples of coatings, coating solutions, and coating compositions include the followings.

A coating containing a metal oxo-hydroxo network having an organic ligand through a metal carbon bond and/or a metal carboxyate bond.

An inorganic oxo/hydroxo base composition.

A coating solution, which comprises an organic solvent; a first organometallic composition, which is represented by the formula: RzSnO_{(2-(z/2)-(x/2))}(OH)ₓ (wherein 0<z≤2 and 0<(z+x)≤4), the formula: R′nSnX₄₋ₙ (wherein n=1 or 2), or a mixture thereof, wherein each of R and R′ is independently a hydrocarbyl group having 1 to 31 carbon atoms, and X is a ligand having a hydrolyzable bond for Sn or a combination thereof, and a hydrolyzable metal compound represented by the formula: MX′ᵥ (wherein M is a metal selected from Groups 2 to 16 of the periodic table of elements, v is a number of 2 to 6, and X′ is a ligand having a hydrolyzable M-X bond or a combination thereof).

A coating solution, which comprises an organic solvent and a first organometallic compound represented by the formula: RSnO_{(3/2-x/2)}(OH)ₓ (wherein 0<x<3), wherein the solution contains tin in an amount of about 0.0025 to about 1.5 M, and R is an alkyl group or cycloalkyl group having 3 to 31 carbon atoms, wherein the alkyl group or cycloalkyl group is bonded to tin at a secondary or tertiary carbon atom.

An aqueous solution of an inorganic pattern-forming precursor, which comprises a mixture of water, a metal suboxide cation, a polyatomic inorganic anion, and a radiation-sensitive ligand containing a peroxide group.

Exposure through a mask (reticle) for forming a predetermined pattern is conducted, and, for example, an i-line, a KrF excimer laser, an ArF excimer laser, an EUV (extreme ultraviolet light), or an EB (electron beam) is used, and the resist underlayer film-forming composition of the present invention is preferably used in the EB (electron beam) or EUV (extreme ultraviolet light) exposure, preferably used in the EUV (extreme ultraviolet light) exposure. In development, an alkaline developer is used, and conditions are appropriately selected from those at a development temperature of 5 to 50° C. for a development time of 10 to 300 seconds. Usable alkaline developers include, for example, an aqueous solution of an alkali, e.g., an inorganic alkali, such as sodium hydroxide, potassium hydroxide, sodium carbonate, sodium silicate, sodium metasilicate, or aqueous ammonia; a primary amine, such as ethylamine or n-propylamine; a secondary amine, such as diethylamine or di-n-butylamine; a tertiary amine, such as triethylamine or methyldiethylamine; an alcohol amine, such as dimethylethanolamine or triethanolamine; a quaternary ammonium salt, such as tetramethylammonium hydroxide, tetraethylammonium hydroxide, or choline; or a cyclic amine, such as pyrrole or piperidine. Further, the above-mentioned aqueous alkali solution which has added thereto an alcohol, such as isopropyl alcohol, or a surfactant, such as a nonionic surfactant, in an appropriate amount may also be used. Of these, a preferred developer is a quaternary ammonium salt, and further preferred are tetramethylammonium hydroxide and choline. Further, for example, a surfactant may be added to the above developer. A method in which development is conducted using an organic solvent, such as butyl acetate, instead of the alkaline developer, to develop a portion of the photoresist of which the alkali dissolution rate remains unimproved may also be used. A substrate having the resist patterned may be produced through the above steps.

Then, using the formed resist pattern as a mask, the resist underlayer film is subjected to dry etching. In this instance, when the above-mentioned inorganic film is formed on the surface of the semiconductor substrate used, the surface of the inorganic film is exposed, and, when the inorganic film is not formed on the surface of the semiconductor substrate used, the surface of the semiconductor substrate is exposed. Then, the substrate is subjected to the step of processing a substrate by a known method (such as a dry etching method), producing a semiconductor device.

### EXAMPLES

Hereinbelow, the present invention will be described in more detail with reference to the following Examples, which should not be construed as limiting the scope of the present invention.

The weight average molecular weight of the polymer shown in the following Synthesis Example 1 and Comparative Synthesis Example 1 in the present specification is the result of the measurement by gel permeation chromatography (hereinafter, referred to simply as “GPC”). In the measurement, a GPC apparatus, manufactured by Tosoh Corp., was used, and the conditions for the measurement and others are as follows.

GPC Column: Shodex KF803L, Shodex KF802, Shodex KF801 [registered trademark] (Showa Denko K. K.)
Column temperature: 40° C.
Solvent: Tetrahydrofuran (TIF)
Flow rate: 1.0 ml/minute
Standard sample: Polystyrene (manufactured by Tosoh Corp.)

### Synthesis Example 1

8.00 g of triglycidylisocyanuric acid (manufactured by Nissan Chemical Corporation), 4.75 g of 3,3′-dithiodipropionic acid (trade name: DTDPA, manufactured by Sakai Chemical Industry Co. Ltd.), 6.69 g of adamantanecarboxyic acid (manufactured by Tokyo Chemical Industry Co., Ltd.), and 0.31 g of tetrabutylphosphonium bromide (manufactured by ACROSS Co., Ltd.) were added to 79.00 g of propylene glycol monomethyl ether and dissolved therein. After purging the reaction vessel with nitrogen gas, the resultant solution was allowed to react at 80° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 6,000, as determined using a conversion calibration curve obtained from the standard polystyrene. The polymer obtained in this synthesis example has structural units represented by the following formulae (1a), (2a), and (3a).

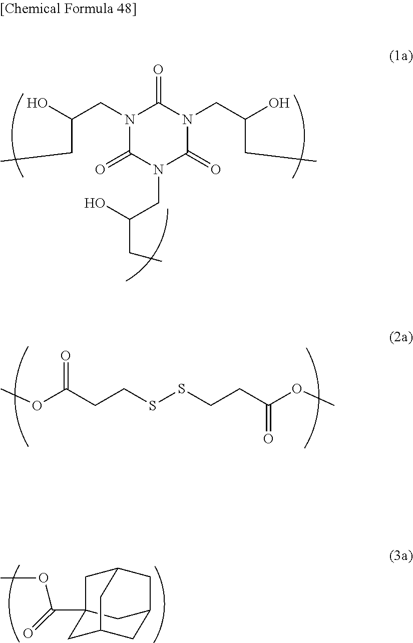

### Synthesis Example 2

8.00 g of triglycidylisocyanuric acid (manufactured by Nissan Chemical Corporation), 4.73 g of 1,3-adamantanedicarboxyic acid (manufactured by Tokyo Chemical Industry Co., Ltd.), 6.69 g of adamantanecarboxyic acid (manufactured by Tokyo Chemical Industry Co., Ltd.), and 0.31 g of tetrabutylphosphonium bromide (manufactured by ACROSS Co., Ltd.) were added to 46.08 g of propylene glycol monomethyl ether and dissolved therein. After purging the reaction vessel with nitrogen gas, the resultant solution was allowed to react at 105° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 8,000, as determined using a conversion calibration curve obtained from the standard polystyrene. The polymer obtained in this synthesis example has structural units represented by the following formulae (1a), (4a), and (3a).

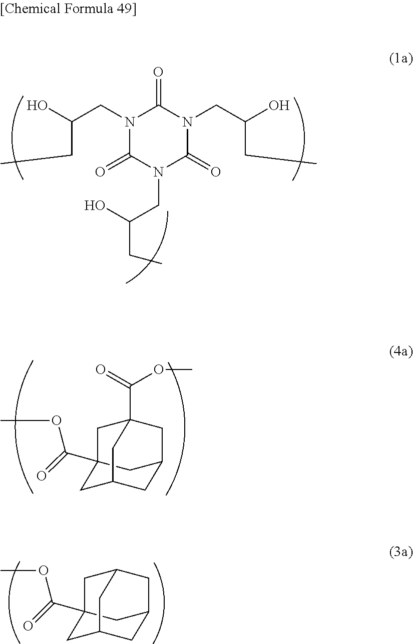

### Synthesis Example 3

3.00 g of triglycidylisocyanuric acid (manufactured by Nissan Chemical Corporation), 2.44 g of 2,2′,6,6′-tetramethylbisphenol S (manufactured by Tokyo Chemical Industry Co., Ltd.), 2.78 g of 4-(methylsulfonyl)benzoic acid (manufactured by Tokyo Chemical Industry Co., Ltd.), and 0.12 g of tetrabutylphosphonium bromide (manufactured by ACROSS Co., Ltd.) were added to 75.03 g of propylene glycol monomethyl ether and dissolved therein. After purging the reaction vessel with nitrogen gas, the resultant solution was allowed to react at 105° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 3,000, as determined using a conversion calibration curve obtained from the standard polystyrene. The polymer obtained in this synthesis example has structural units represented by the following formulae (1a), (6a), and (7a).

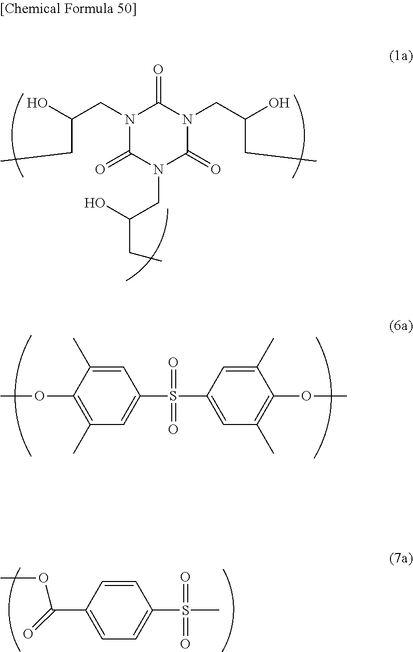

### Synthesis Example 4

4.00 g of triglycidylisocyanuric acid (manufactured by Nissan Chemical Corporation), 4.72 g of 3,3′,4,4′-diphenylsulfonetetracarboxyic dianhydride (manufactured by Tokyo Chemical Industry Co., Ltd.), 2.63 g of 4-(methylsulfonyl)benzoic acid (manufactured by Tokyo Chemical Industry Co., Ltd.), and 0.16 g of tetrabutylphosphonium bromide (manufactured by ACROSS Co., Ltd.) were added to 75.03 g of propylene glycol monomethyl ether and dissolved therein. After purging the reaction vessel with nitrogen gas, the resultant solution was allowed to react at 120° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 7,000, as determined using a conversion calibration curve obtained from the standard polystyrene. The polymer obtained in this synthesis example has structural units represented by the following formulae (1a), (8a), and (7a).

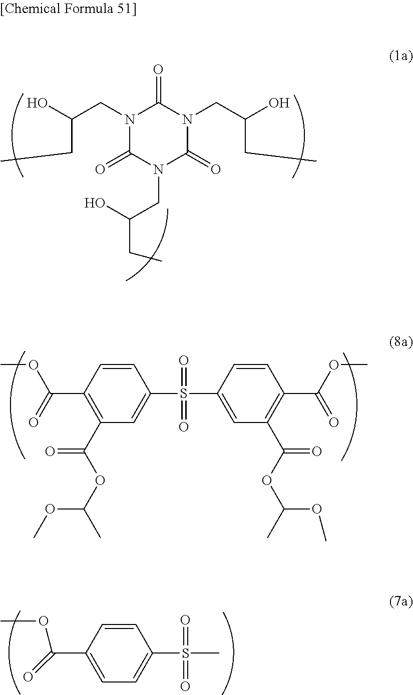

### Comparative Synthesis Example 1

3.00 g of monoallyldiglycidylisocyanuric acid (manufactured by Shikoku Chemicals Corporation), 1.91 g of 3,3′-dithiodipropionic acid (trade name: DTDPA, manufactured by Sakai Chemical Industry Co. Ltd.), 0.57 g of adamantanecarboxyic acid (manufactured by Tokyo Chemical Industry Co., Ltd.), and 0.14 g of tetrabutylphosphonium bromide (manufactured by ACROSS Co., Ltd.) were added to 6.87 g of propylene glycol monomethyl ether and dissolved therein. After purging the reaction vessel with nitrogen gas, the resultant solution was allowed to react at 105° C. for 8 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 5,000, as determined using a conversion calibration curve obtained from the standard polystyrene. The polymer obtained in this synthesis example has structural units represented by the following formulae (1b), (2a), and (3a).

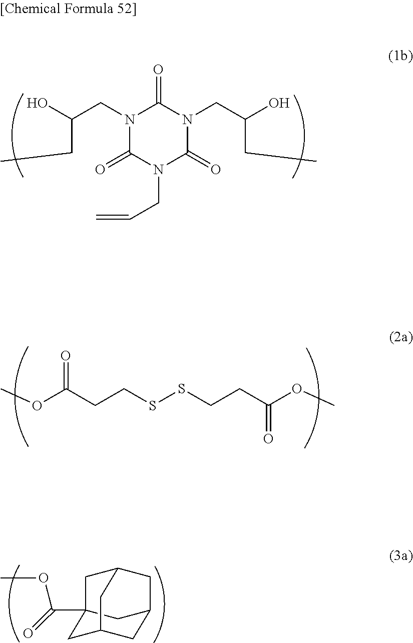

### Comparative Synthesis Example 2

3.00 g of monoallyldiglycidylisocyanuric acid (manufactured by Shikoku Chemicals Corporation), 2.04 g of 1,3-adamantanedicarboxyic acid (manufactured by Tokyo Chemical Industry Co., Ltd.), 0.57 g of adamantanecarboxyic acid (manufactured by Tokyo Chemical Industry Co., Ltd.), and 0.04 g of tetrabutylphosphonium bromide (manufactured by ACROSS Co., Ltd.) were added to 15.08 g of propylene glycol monomethyl ether and dissolved therein. After purging the reaction vessel with nitrogen gas, the resultant solution was allowed to react at 105° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 8,300, as determined using a conversion calibration curve obtained from the standard polystyrene. The polymer obtained in this synthesis example has structural units represented by the following formulae (1b), (4a), and (3a).

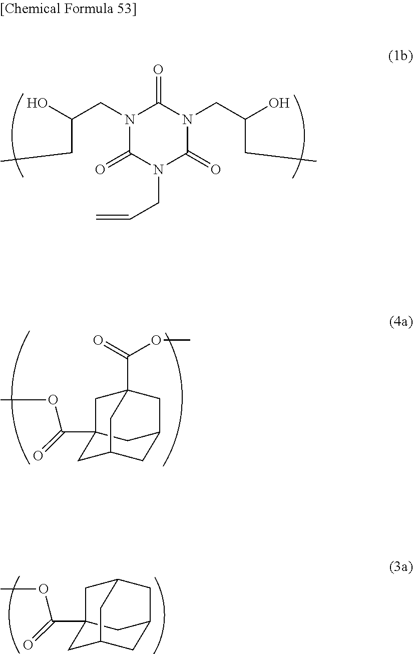

### Reference Synthesis Example 3

5.00 g of monoallyldiglycidylisocyanuric acid (manufactured by Shikoku Chemicals Corporation), 4.64 g of 2,2′,6,6′-tetramethylbisphenol S (manufactured by Tokyo Chemical Industry Co., Ltd.), 1.07 g of 4-(methylsulfonyl)benzoic acid (manufactured by Tokyo Chemical Industry Co., Ltd.), and 0.06 g of tetrabutylphosphonium bromide (manufactured by ACROSS Co., Ltd.) were added to 25.03 g of propylene glycol monomethyl ether and dissolved therein. After purging the reaction vessel with nitrogen gas, the resultant solution was allowed to react at 105° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 6,200, as determined using a conversion calibration curve obtained from the standard polystyrene. The polymer obtained in this synthesis example has structural units represented by the following formulae (1b), (6a), and (7a).

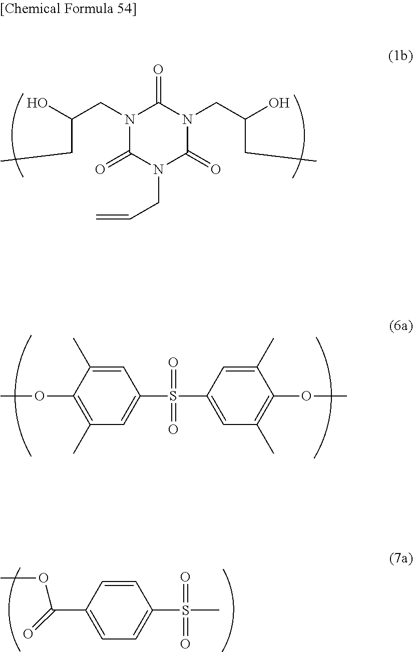

### Comparative Synthesis Example 4

3.00 g of monoallyldiglycidylisocyanuric acid (manufactured by Shikoku Chemicals Corporation), 3.27 g of 3,3′,4,4′-diphenylsulfonetetracarboxyic dianhydride (manufactured by Tokyo Chemical Industry Co., Ltd.), 0.64 g of 4-(methylsulfonyl)benzoic acid (manufactured by Tokyo Chemical Industry Co., Ltd.), and 0.03 g of tetrabutylphosphonium bromide (manufactured by ACROSS Co., Ltd.) were added to 27.66 g of propylene glycol monomethyl ether and dissolved therein. After purging the reaction vessel with nitrogen gas, the resultant solution was allowed to react at 105° C. for 24 hours to obtain a polymer solution. The obtained polymer solution did not get cloudy even when cooled to room temperature, thus the polymer had a good solubility in propylene glycol monomethyl ether. GPC analysis showed that the polymer had a weight average molecular weight of 8,300, as determined using a conversion calibration curve obtained from the standard polystyrene. The polymer obtained in this synthesis example has structural units represented by the following formulae (1b), (8a), and (7a).

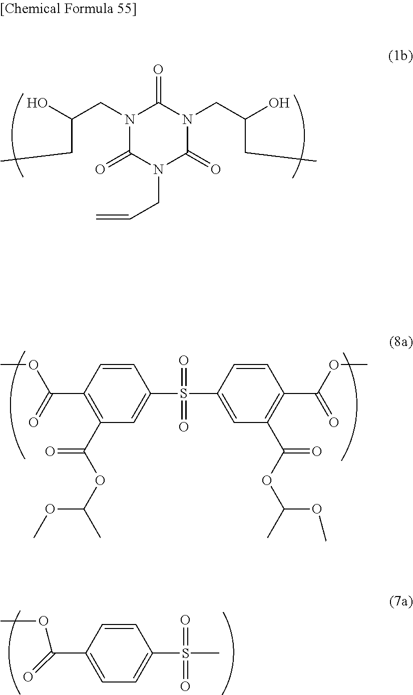

### Example 1

To 0.43 g of the polymer solution (solid content: 16.4% by weight) obtained in Synthesis Example 1 above were added 0.02 g of tetramethoxymethylglycoluril (manufactured by Nihon Cytec Industries Inc.), 0.003 g of pyridinium phenolsulfonate, 44.5 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Example 2

To 0.47 g of the polymer solution (solid content: 17.8% by weight) obtained in Synthesis Example 2 above were added 0.02 g of tetramethoxymethylglycoluril (manufactured by Nihon Cytec Industries Inc.), 0.003 g of pyridinium phenolsulfonate, 44.6 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Example 3

To 0.47 g of the polymer solution (solid content: 18.3% by weight) obtained in Synthesis Example 3 above were added 0.02 g of tetramethoxymethylglycoluril (manufactured by Nihon Cytec Industries Inc.), 0.003 g of pyridinium phenolsulfonate, 44.6 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Example 4

To 0.48 g of the polymer solution (solid content: 17.7% by weight) obtained in Synthesis Example 4 above were added 0.02 g of tetramethoxymethylglycoluril (manufactured by Nihon Cytec Industries Inc.), 0.003 g of pyridinium phenolsulfonate, 44.4 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Comparative Example 1

To 0.47 g of the polymer solution (solid content: 18.0% by weight) obtained in Comparative Synthesis Example 1 above were added 0.02 g of tetramethoxymethylglycoluril (manufactured by Nihon Cytec Industries Inc.), 0.003 g of pyridinium phenolsulfonate, 44.6 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Comparative Example 2

To 0.47 g of the polymer solution (solid content: 18.0% by weight) obtained in Comparative Synthesis Example 2 above were added 0.02 g of tetramethoxymethylglycoluril (manufactured by Nihon Cytec Industries Inc.), 0.003 g of pyridinium phenolsulfonate, 44.6 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Reference Example 3

To 0.43 g of the polymer solution (solid content: 18.1% by weight) obtained in Reference Synthesis Example 3 above were added 0.02 g of tetramethoxymethylglycoluril (manufactured by Nihon Cytec Industries Inc.), 0.003 g of pyridinium phenolsulfonate, 43.0 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Comparative Example 4

To 0.29 g of the polymer solution (solid content: 26.7% by weight) obtained in Comparative Synthesis Example 4 above were added 0.02 g of tetramethoxymethylglycoluril (manufactured by Nihon Cytec Industries Inc.), 0.003 g of pyridinium phenolsulfonate, 44.0 g of propylene glycol monomethyl ether, and 4.99 g of propylene glycol monomethyl ether acetate and dissolved. Then, the resultant solution was filtered using a polyethylene microfilter having a pore diameter of 0.05 μm to prepare a resist underlayer film-forming composition for lithography.

### Test for Dissolution into a Photoresist Solvent

Each of the resist underlayer film-forming compositions in Examples 1 to 4, Comparative Examples 1 and 2, Reference Example 3, and Comparative Example 4 was applied by a spinner onto a semiconductor substrate, i.e., a silicon wafer. The silicon wafer was placed on a hotplate and baked at 205° C. for one minute to form a resist underlayer film (thickness: 5 nm). The formed resist underlayer film was immersed in the solvents used in the photoresist, i.e., ethyl lactate and propylene glycol monomethyl ether, to confirm that the film was insoluble in any of these solvents.

### Formation of a Positive Resist Pattern by Electron Beam Lithography System

Each of the resist underlayer film-forming compositions in Examples 1 and 2 and Comparative Examples 1 and 2 was applied onto a silicon wafer using a spinner. The silicon wafer was baked on a hotplate at 205° C. for 60 seconds to obtain a resist underlayer film having a thickness of 5 nm. An EUV positive resist solution (containing a methacrylic polymer) was applied by spin coating onto the obtained resist underlayer film, and heated at 130° C. for 60 seconds to form an EUV resist film. The formed resist film was exposed under the predetermined conditions using an electron beam lithography system (ELS-G130). The exposed resist film was baked (PEB) at 100° C. for 60 seconds, cooled to room temperature on a cooling plate, and developed using an alkaline developer (2.38% TMAH), to form a 26 nm pillar pattern/52 nm pitch resist pattern. The measurement of the length of resist pattern was carried out with a scanning electron microscope (CG4100, manufactured by Hitachi High-Technologies Corporation). In the formation of the resist pattern, the formed resist pattern was estimated by the rating “Excellent” when a pillar pattern with a CD size of 31 nm was formed, and by the rating “Poor” when collapse or peeling of the pillar pattern was seen. In addition, a comparison was made between the amounts of exposure required for forming a pillar pattern with a CD size of 31 nm, in terms of the exposure value standardized based on Comparative Example 1.

TABLE 1

| | Pillar pattern with | Standardized |
|---|---|---|
| | CD size of 31 nm | exposure value |
| Example 1 | Excellent | 0.97 |
| Example 2 | Excellent | 0.97 |
| Comparative | Poor | 1.00 |
| Example 1 | | |
| Comparative | Poor | 0.99 |
| Example 2 | | |

In both Examples 1 and 2, collapse or peeling of the pillar pattern could be more successfully suppressed, as compared to Comparative Examples 1 and 2. It was confirmed by the results that the compositions in Examples 1 and 2 had a good pattern-forming capacity. In addition, with respect to the amount of required exposure, the results confirmed that, in both Examples 1 and 2, the pattern formation could be made with lesser amount of exposure, as compared to Comparative Examples 1 and 2.

### Formation of a Negative Resist Pattern by Electron Beam Lithography System

Each of the resist underlayer film-forming compositions in Examples 3 and 4 and Comparative Example 4 was applied onto a silicon wafer using a spinner. The silicon wafer was baked on a hotplate at 205° C. for 60 seconds to obtain a resist underlayer film having a thickness of 5 nm. An EUV negative resist solution was applied by spin coating onto the obtained resist underlayer film, and heated at 100° C. for 60 seconds to form an EUV resist film. The formed resist film was exposed under the predetermined conditions using an electron beam lithography system (ELS-G130). The exposed resist film was baked (PEB) at 100° C. for 60 seconds, cooled to room temperature on a cooling plate, and developed using butyl acetate, to form a 23 nm pillar pattern/46 nm pitch resist pattern. The measurement of the length of resist pattern was carried out with a scanning electron microscope (CG4100, manufactured by Hitachi High-Technologies Corporation). The thus obtained photoresist pattern was evaluated by observing from the upper portion of the pattern. In the formation of the resist pattern, the formed resist pattern was estimated by the rating “Excellent” when a pillar pattern with a CD size of 20 nm was formed, and by the rating “Poor” when collapse or peeling of the pillar pattern was seen. In addition, a comparison was made between the amounts of exposure required for forming a pillar pattern with a CD size of 31 nm.

TABLE 2

| | Pillar pattern with |
|---|---|
| | CD size of 20 nm |
| Example 3 | Excellent |
| Example 4 | Excellent |
| Comparative | Poor |
| Example 4 | |

In Examples 3 and 4, collapse or peeling of the pillar pattern could be more successfully suppressed, as compared to Comparative Example 4. It was confirmed by the results that the compositions in Examples 3 and 4 had a good pattern-forming capacity.

It was found from the above results that the resist underlayer film-forming composition of the present invention exhibited a better lithography performance, as compared to the prior art.

### INDUSTRIAL APPLICABILITY

It is possible for the resist underlayer film-forming composition of the present invention to provide a composition for forming a resist underlayer film that is capable of forming a desired resist pattern, a method for producing a substrate having a resist pattern using the resist underlayer film-forming composition, and a method for producing a semiconductor device.

1. A resist underlayer film-forming composition comprising a solvent and a reaction product of:
Compound (A) represented by the following formula (1): 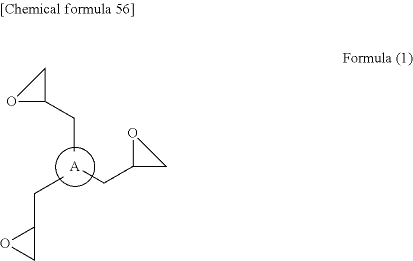
wherein A represents an organic group having an aliphatic ring, aromatic ring, or heterocycle,
Compound (B) having two functional groups having reactivity with an epoxy group, and
Compound (C) having a functional group having reactivity with an epoxy group,
wherein the reaction product is dissolved in the solvent.

2. The resist underlayer film-forming composition according to claim 1, wherein A in formula (1) is a heterocycle.

3. The resist underlayer film-forming composition according to claim 2, wherein the heterocycle is a triazine.

4. The resist underlayer film-forming composition according to claim 1, wherein Compound (B) is a compound having two functional groups having reactivity with an epoxy group, and having an aliphatic ring, aromatic ring, heterocycle, fluorine atom, iodine atom, or sulfur atom.

5. The resist underlayer film-forming composition according to claim 1, wherein Compound (C) is a compound having a functional group having reactivity with an epoxy group, and having an aliphatic or aromatic ring optionally substituted with a substituent.

6. A resist underlayer film-forming composition comprising a solvent and a reaction product (a) of:
Compound (A) represented by the following formula (1): 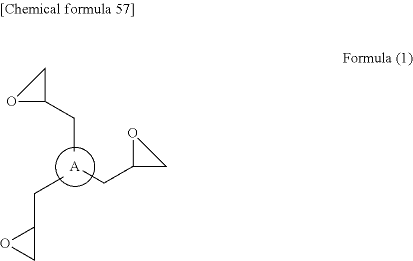
wherein A represents an organic group having an aliphatic ring, aromatic ring, or heterocycle,
and
Compound (B) having two functional groups having reactivity with an epoxy group, and having no disulfide bond,
wherein the reaction product (a) is dissolved in the solvent.

7. The resist underlayer film-forming composition according to claim 1, further comprising an acid generator.

8. The resist underlayer film-forming composition according to claim 1, further comprising a crosslinking agent.

9. A resist underlayer film which is a baked material of an applied film comprising the resist underlayer film-forming composition according to claim 1.

10. A method for producing a patterned substrate, comprising the steps of:
applying the resist underlayer film-forming composition according to claim 1 onto a semiconductor substrate and baking the applied composition to form a resist underlayer film;
applying a resist onto the resist underlayer film and baking the applied resist to form a resist film;
subjecting the semiconductor substrate covered with the resist underlayer film and the resist to exposure; and
subjecting the exposed resist film to development and patterning.

11. A method for producing a semiconductor device, comprising the steps of:
forming a resist underlayer film comprising the resist underlayer film-forming composition according to claim 1 on a semiconductor substrate;
forming a resist film on the resist underlayer film;
irradiating the resist film with a light or electron beam and then developing the irradiated resist film to form a resist pattern;
etching the resist underlayer film through the formed resist pattern to form a patterned resist underlayer film; and
processing the semiconductor substrate using the patterned resist underlayer film.
